(19) United States
(12) Patent Application Publication
(10) Pub. No.: US 2025/0359102 A1
(43) Pub. Date: Nov. 20, 2025

(54) SEMICONDUCTOR DEVICES AND METHODS FOR FORMING THE SAME

(71) Applicant: Taiwan Semiconductor Manufacturing Company, Ltd., Hsinchu (TW)

(72) Inventors: Jia-Ni YU, Hsinchu (TW); Lung-Kun CHU, Hsinchu (TW); Hsin-Jung LEE, Hsinchu (TW); Kuo-Cheng CHIANG, Hsinchu (TW); Chih-Hao WANG, Hsinchu (TW)

(21) Appl. No.: 18/927,391

(22) Filed: Oct. 25, 2024

Related U.S. Application Data
(60) Provisional application No. 63/648,051, filed on May 15, 2024.

(51) Int. Cl. H01L 29/66; H01L 29/06; H01L 29/423; H01L 29/775; H01L 29/786

(52) U.S. Cl. CPC H10D 30/014; H10D 30/43; H10D 30/6735; H10D 30/6757; H10D 62/121; H10D 64/017; H10D 64/018

(57) ABSTRACT

Provided is a method for forming semiconductor devices. This method includes forming a fin-shaped structure comprising a fin stack portion including alternatively stacked first and second semiconductor portions, forming a dummy gate structure comprising a dummy gate stack across a channel region of the fin-shaped structure, forming source/drain features over source/drain regions of the fin-shaped structure on opposite sides of the dummy gate structure, removing the dummy gate stack to form a gate trench exposing sidewalls of the first and semiconductor portions, selectively removing the first semiconductor portions to release the second semiconductor layer portions in the channel region as channel members, depositing a dielectric material to fill gaps between the channel members; selectively growing semiconductor caps on the sidewalls of the channel members, removing the deposited dielectric material and forming a gate stack to surround the semiconductor caps and the channel members and fills the gaps.

### PRIORITY CLAIM AND CROSS-REFERENCE

This application claims benefit of U.S. Provisional Patent Application No. 63/648,051 filed May 15, 2024, which is incorporated by reference herein in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method for fabricating a gate-all-around (GAA) device, in accordance with some embodiments of the present disclosure.

FIGS. 2-15F illustrate various views of the GAA device during a fabrication process according to the method of FIG. 1, in accordance with some embodiments of the present disclosure.

FIG. 16 is a flowchart of a method for fabricating a gate-all-around (GAA) device, in accordance with some embodiments of the present disclosure.

FIGS. 17A-27D illustrate various views of the GAA device during a fabrication process according to the method of FIG. 16, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some non-planar transistor architectures, such as vertical field effect transistors (VFETs) and nanosheet field effect transistors (NSFETs), employ semiconductor channels with various gate-all-around (GAA) technologies to achieve increased device density, greater power efficiency, and some increased performance over lateral devices. In NSFET embodiments, the gate stack wraps around the full perimeter of each nanosheet, enabling fuller depletion in the channel region, and reducing short-channel effects due to steeper subthreshold swing (SS) and smaller drain induced barrier lowering (DIBL). The wrap-around gate structures and source/drain contacts used in nanosheet-based devices also enable greater management of leakage current and parasitic capacitance in the active regions, even as drive currents increase.

In a GAA configuration, a nanosheet-based FET includes a source structure, a drain structure and stacked nanosheet channels between the source and drain structures. A gate surrounds the stacked nanosheet channels and regulates electron flow through the nanosheet channels between the source and drain structures. GAA nanosheet FETs are fabricated by forming alternating layers of channel nanosheets and sacrificial nanosheets. The sacrificial nanosheets are released from the channel nanosheets before the FET device is finalized.

However, silicon-channel-based nanosheet GAA devices, where silicon channels are typically formed (released) by removing adjacent SiGe nanosheets in a process known as “sheet formation” (SHF), commonly face challenges due to the reduction in channel width during the removal of sacrificial nanosheet in a replacement metal gate process. The etching of sacrificial nanosheets also removes the channel nanosheet material, resulting in a dumbbell-shaped channel profile. This shape unavoidably increases parasitic capacitance (C_{eff}) and reduces direct current (DC), thereby diminishing the overall performance of nanosheet GAA devices.

Embodiments of the present disclosure enlarge the channel width by selectively depositing semiconductor caps on the sidewalls of the channels in a gate-replacement process to enhance device performance. These semiconductor caps are designed either to compensate for the width loss of the channel nanosheets caused by the etching process used to remove sacrificial nanosheets or to serve as sacrificial components consumed during the etching process, thereby preventing the channel nanosheets from being etched. As a result, improvement in the dumbbell-shaped channel profile can reduce C_{eff} and increase DC, thereby enhancing overall nanosheet GAA device performance.

The GAA transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structures.

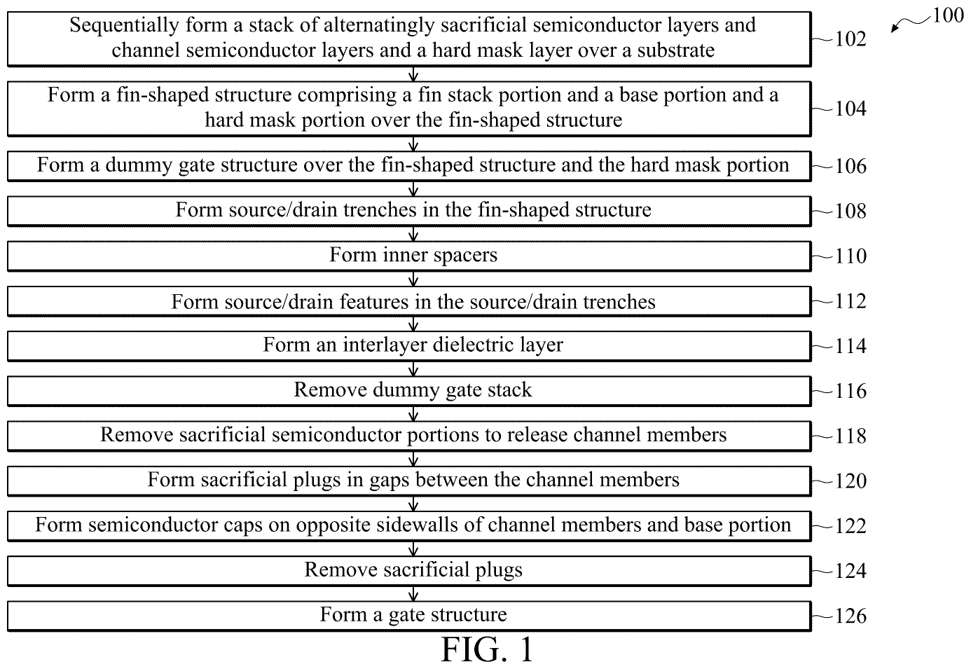

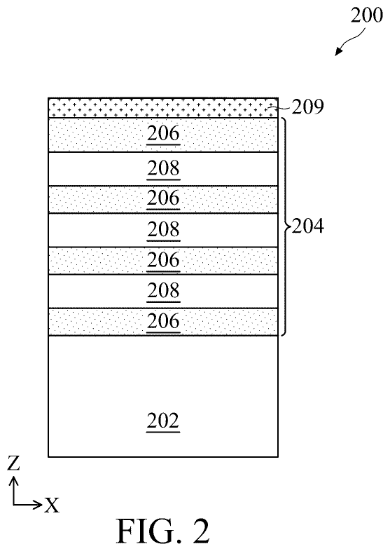

FIG. 1 is a flowchart of a method 100 of forming a GAA device 200, in accordance with some embodiments of the present disclosure. FIGS. 2-15F are various views of the GAA device 200 at various stages of the method 100, in accordance with some embodiments. Some embodiments of method 100 are described below in conjunction with FIGS. 2-15F with reference to the GAA device 200. The method 100 is merely an example and is not intended to limit the present disclosure beyond what is explicitly recited in the claims. Additional operations can be provided before, during, and after the method 100, and some operations described can be replaced, eliminated, or moved around for additional embodiments of the method.

Referring to FIGS. 1 and 2, the method 100 includes operation 102, where an initial structure of the GAA device 200 is provided. The initial structure includes a substrate 202, a stack 204 of alternating epitaxial semiconductor layers over the substrate 202, and a hard mask layer 209 over the stack 204. FIG. 2 is a cross-sectional view of the GAA device 200 after forming the stack 204 of alternating epitaxial semiconductor layers over the substrate 202 followed by forming the hard mask layer 209 over the stack 204.

The substrate 202 can be any suitable substrate, and can be processed with various features. In some embodiments, the substrate 202 may be a semiconductor substrate such as a silicon substrate. In some embodiments, the substrate 202 includes various layers, including conductive or insulating layers formed on a semiconductor substrate. The substrate 202 may include various doping configurations. For example, different doping profiles (e.g., n wells, p wells) may be formed on the substrate 202 in regions designed for different device types (e.g., n-type FETs, p-type FETs). The suitable doping may include ion implantation of dopants and/or diffusion processes. The substrate 202 typically has isolation features (e.g., shallow trench isolation (STI) features) interposing the regions providing different device types. The substrate 202 includes other semiconductors such as germanium or diamond. Alternatively, the substrate 202 includes a compound semiconductor such as silicon carbide (SiC), gallium arsenic, gallium phosphide, indium phosphide, indium arsenide, indium antimonide; an alloy semiconductor, such as SiGe, GaAsP, AlInAs, AlGaAs, GalnAs, GalnP, GaInAsP, and/or other suitable materials. Further, the substrate 202 may optionally include an epitaxial layer, may be strained for performance enhancement, may include a silicon-on-insulator structure, and/or have other suitable enhancement features.

The stack 204 of alternating epitaxial semiconductor layers are blanketly deposited on the substrate 202. The stack 204 comprises alternating sacrificial semiconductor layers 206 and channel semiconductor layers 208, wherein each channel semiconductor layer 208 is disposed between the sacrificial semiconductor layers 206. In some embodiments, the sacrificial semiconductor layers 206 include a first semiconductor material, and the channel semiconductor layers 208 include a second semiconductor material that is different from the first semiconductor material. The materials of sacrificial semiconductor layers 206 and channel semiconductor layers 208 may be chosen based on providing different etching selectivities. For example, in some embodiments, the first semiconductor material may comprise germanium (Ge) or silicon germanium (SiGe), whereas the second semiconductor material may comprise silicon (Si). In some alternative embodiments, the first semiconductor material includes SiGe having a first Ge content and the second semiconductor material includes SiGe having a second Ge content lower than the first Ge content. In various embodiments, the sacrificial semiconductor layers 206 and the channel semiconductor layer 208 are substantially dopant-free (i.e., having an extrinsic dopant concentration less than about 1×10¹⁷ cm⁻³).

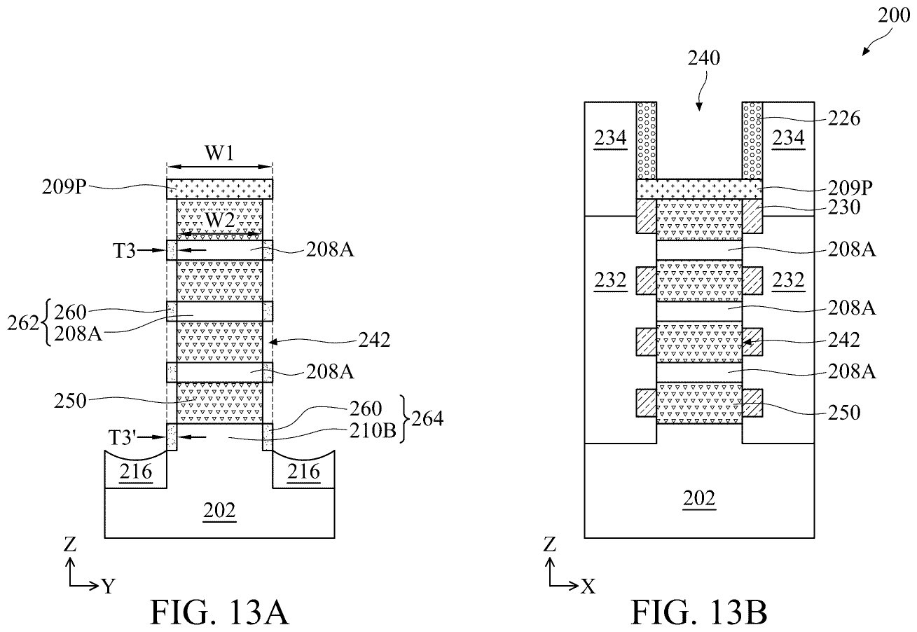

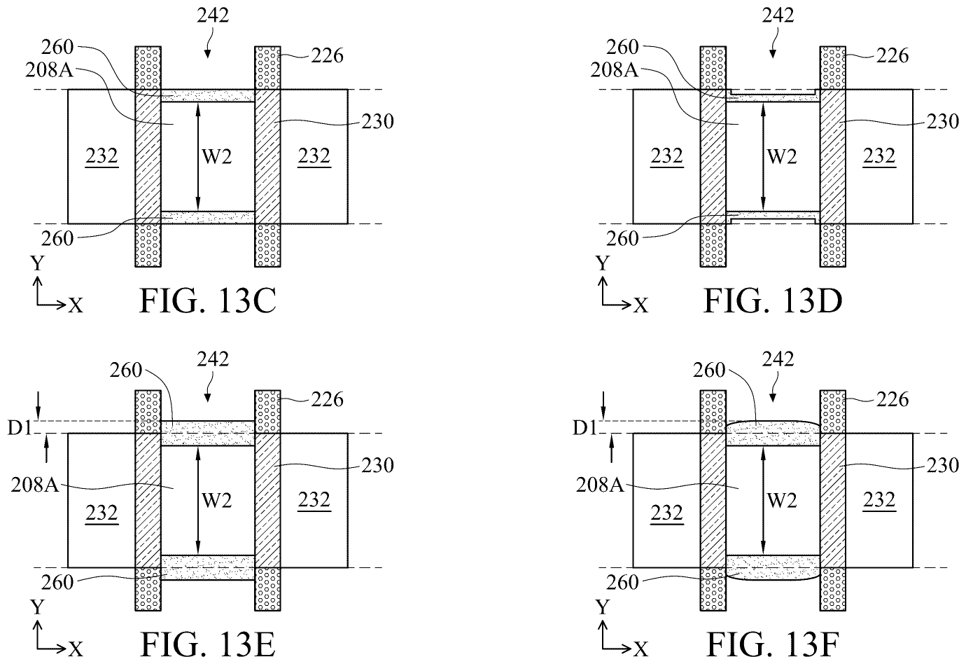

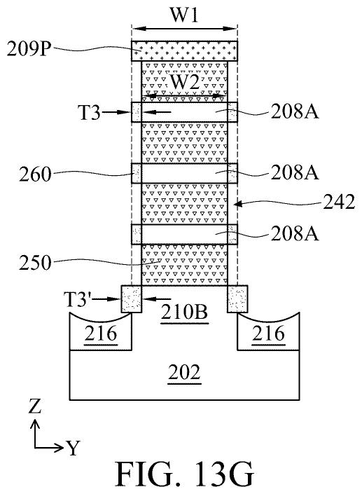

In some embodiments, the sacrificial semiconductor layers 206 may be removed in a later process, thereby leaving the channel semiconductor layers 208 which define channel nanostructures (e.g., 262 of FIG. 13A) for the GAA device 200. The thickness of sacrificial semiconductor layers 206 thus determines the spacing between adjacent channel nanostructures (e.g., 262 of FIG. 13A). In some embodiments, the thickness of the sacrificial semiconductor layers 206 may range from about 8 nm to about 15 nm. The thickness of the channel semiconductor layers 208 is chosen based on, for example, manufacturing considerations, transistor performance considerations, and the like. In some embodiments, the thickness of the channel semiconductor layers 208 may range from about 4 nm to about 10 nm.

The number of sacrificial semiconductor layers 206 and channel semiconductor layers 208 depends on the desired number of channel nanostructures (e.g., 262 of FIG. 13A) in the GAA device 200. In some embodiments, the number of channel semiconductor layers 208 is from, for example, 2 to 10, to form a stack of 2 to 10 vertically separated channel nanostructures. In some embodiments and as illustrated in FIG. 2, the stack 204 includes four (4) layers of sacrificial semiconductor layers 206 and three (3) layers of channel semiconductor layers 208.

The sacrificial semiconductor layers 206 and channel semiconductor layers 208 are epitaxially grown layer-by-layer from a top surface of the substrate 202. In some embodiments, the sacrificial semiconductor layers 206 and channel semiconductor layers 208 are grown by a molecular beam epitaxy (MBE) process, a chemical vapor deposition (CVD) process such as a metal organic CVD (MOCVD) process, or other suitable epitaxy growth processes. The epitaxy growth results in the sacrificial semiconductor layers 206 and the channel semiconductor layers 208 having the same crystal orientation as the substrate 202.

The hard mask layer 209 is formed over the topmost surface of the stack 204. In some embodiments, the hard mask layer 209 includes a dielectric material such as, for example, silicon nitride (SiN), silicon carbon nitride (SiCN), silicon oxycarbide (SiOC), silicon oxycarbon nitride (SiOCN), or a combination thereof. In some embodiments, the hard mask layer 209 is formed by chemical CVD, plasma enhanced CVD (PECVD), physical vapor deposition (PVD), atomic layer deposition (ALD), or other suitable deposition processes. In some embodiments, the hard mask layer 209 may have a double-layer structure including a pad oxide layer and a pad nitride layer formed over the pad oxide layer. In some embodiments, the pad oxide layer includes silicon oxide, which can be formed by thermal oxidation. The pad nitride layer includes SiN, which can be formed by CVD, PECVD, PVD, ALD, or other suitable deposition processes. The hard mask layer 209 is used to protect portions of the substrate 202 and the stack 204 and is used to define a pattern (e.g., fins) as described below.

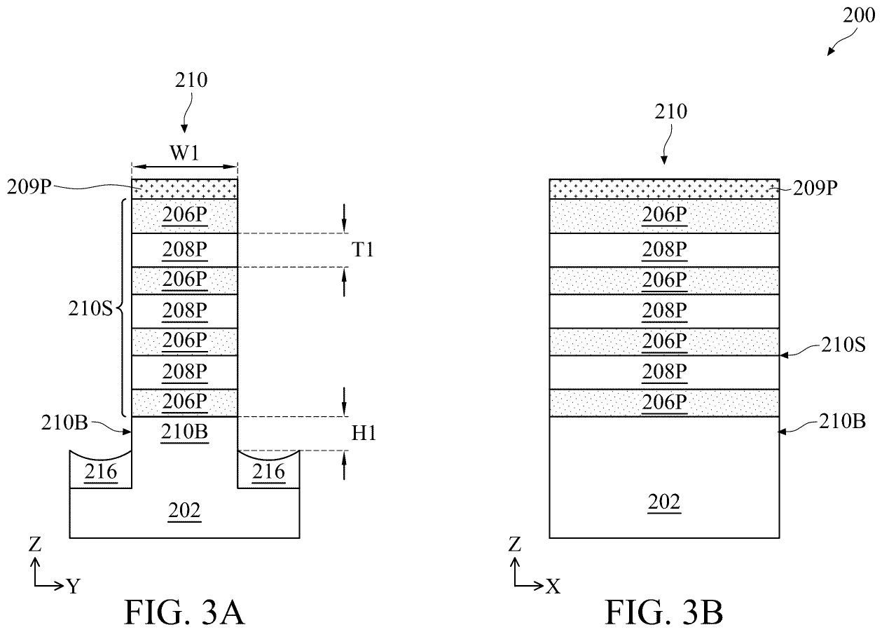

Referring to FIGS. 1 and 3A-3B, the method 100 proceeds to operation 104, where a fin-shaped structure 210 is formed from the stack 204, in accordance with some embodiments. FIGS. 3A and 3B are cross-sectional views of the GAA device 200 after forming the fin-shaped structure 210. It should be noted that although a single fin-shaped structure 210 is illustrated in FIG. 3A, any number of fin-shaped structures 210 may be formed.

In some embodiments, the stack 204 and a portion of the substrate 202 are patterned to form the fin-shaped structure 210. The fin-shaped structure 210 extends vertically along the Z-direction from the substrate 202 and has a length dimension along the X direction and a width dimension along the Y direction. The width of the fin-shaped structure 210 may range from about 10 nm to about 90 nm. The fin-shaped structure 210 includes a base portion 210B (e.g. fin portion/protrusion) and a fin stack portion 210S. The base portion 210B is formed from the substrate 202, while the fin stack portion 210S is formed from the stack 204 and includes portions of the sacrificial semiconductor layers 206 (herein referred to as sacrificial semiconductor portions 206P) and portions of the channel semiconductor layers 208 (herein referred to as channel semiconductor portions 208P).

In some embodiments, the fin-shaped structures 210 may be formed using photolithography and etch processes. During a photolithography process, a photoresist layer is first applied to the hard mask layer 209 by, for example, spin coating. Then, the photoresist layer is exposed according to a mask of patterns, and is developed to form the patterns in the photoresist layer. The photoresist layer with the patterns can be used as an etch mask to pattern other layers. In some embodiments, patterning the photoresist layer is performed using an extreme ultraviolet (EUV) light lithography process. The patterned photoresist layer is then used to protect regions of the substrate 202 and the sacrificial semiconductor layers 206 and channel semiconductor layers 208 formed thereupon, while an etching process forms the fin-shaped structure 210. In some embodiments, the etching process may be a dry etching process such as plasma etching or reactive ion etching (RIE), a wet etching process, or a combination thereof.

In various other embodiments, the fin-shaped structure 210 may be formed using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Mandrels are formed alongside the patterned sacrificial layer using a self-aligned process. The sacrificial layer is then removed, and the remaining mandrels are then used as an etch mask to pattern the stack 204 and the substrate 202 to provide the fin-shaped structure 210.

Subsequently, an isolation feature 216 may be formed adjacent and around the base portion 210B of the fin-shaped structure 210. The isolation feature 216 is disposed between the fin-shaped structure 210 and another fin-shaped structure 210 (not shown). The isolation feature 216 may also be referred to as a shallow trench isolation (STI) feature. In an example process, a dielectric layer is first deposited over the substrate 202, filling the trenches between the fin-shaped structure 210 and a neighboring fin-shaped structure 210 with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, an atomic layer deposition (ALD) process, a physical vapor deposition (PVD) process, spin-on coating, and/or other suitable process. The deposited dielectric material is then planarized, for example, by a chemical mechanical polishing (CMP) process. The planarized dielectric layer is further recessed by a dry etching process, a wet etching process, and/or a combination thereof to form the isolation feature 216. In some embodiments, a top surface of the isolation feature 216 is substantially coplanar with or lower than a bottom surface of the lowermost sacrificial semiconductor portions 206P. In some embodiments and as shown in FIG. 3A, the fin stack portion 210S of the fin-shaped structure 210 and the base portion 210B rise above the isolation feature 216. The portion of the base portion 210B that is above the isolation feature 216 may have a height H1 the same as or greater than the thickness T1 of the channel semiconductor portions 208P. As shown in FIGS. 3A and 3B, the hard mask layer 209 is formed from a dielectric material having a high etching selectivity comparing to the isolation feature 216, and remains in the structure after the formation of the isolation feature 216. The remaining portion of the hard mask layer 209 is referred to as hard mask portion 209P.

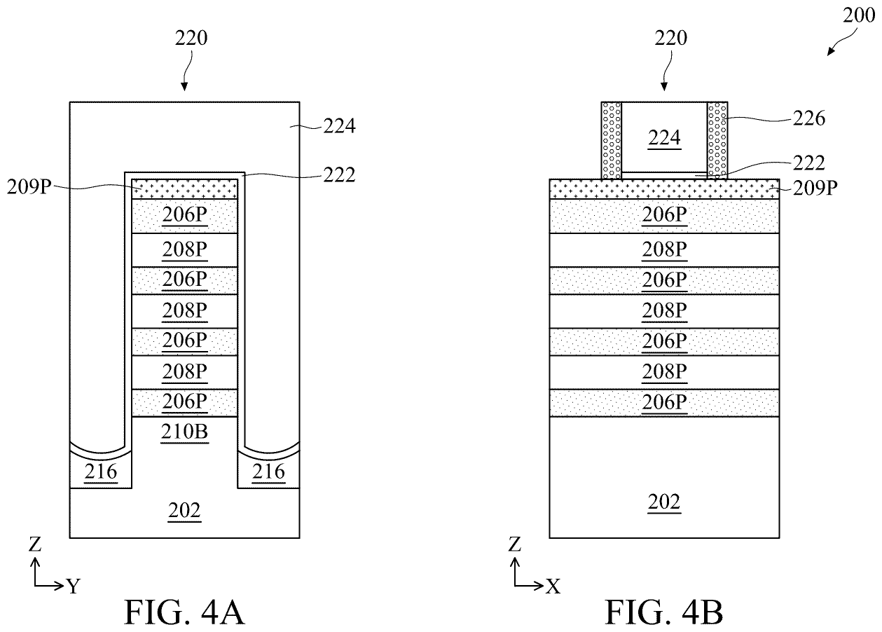

Referring to FIGS. 1 and 4A-4B, the method 100 proceeds to operation 106, where a dummy gate structure 220 is formed over the hard mask portion 209P and fin-shaped structure 210, in accordance with some embodiments. FIGS. 4A and 4B are cross-sectional views of the GAA device 200 after forming the dummy gate structure 220. The dummy gate structure 220 is formed across the hard mask portion 209P and the fin-shaped structure 210, along the sidewalls of the hard mask portion 209P and the fin-shaped structure 210 and over the top surface of the hard mask portion 209P.

The dummy gate structure 220 includes a dummy gate stack (222, 224) and gate spacers 226. In accordance with embodiments of the present disclosure, the dummy gate stack (222, 224) will be replaced with a metal gate stack.

In some embodiments, the dummy gate stack (222, 224) includes a dummy gate dielectric 222 and a dummy gate electrode 224 on the dummy gate dielectric 222. In some embodiments, the dummy gate stack (222, 224) may further include a dummy gate cap (not shown) on top of the dummy gate electrode 224.

In some embodiments, the dummy gate dielectric 222 may be made of silicon oxide, silicon nitride, or silicon oxynitride. The dummy gate electrode 224 may be made of silicon such as polycrystalline silicon or amorphous silicon. In some embodiments, the dummy gate stack (222, 224) may be formed by first conformally depositing a dummy gate dielectric layer over the hard mask portion 209P, the fin-shaped structure 210, and the isolation feature 216. A dummy gate electrode layer is then blanketly deposited on the dummy gate dielectric layer such that the hard mask portion 209P and the fin-shaped structure 210 are fully embedded in the dummy gate electrode layer. The thickness of the dummy gate dielectric layer may range from about 1 nm to about 5 nm in some embodiments. The thickness of the dummy gate electrode layer may range from about 100 nm to about 200 nm in some embodiments. In some embodiments, the dummy gate electrode layer is subjected to a planarization operation. The dummy gate dielectric layer and the dummy gate electrode layer may be deposited using CVD, PECVD, PVD, ALD, or other suitable deposition processes. Subsequently, the dummy gate dielectric layer and the dummy gate electrode layer are patterned using photolithography and etching processes. For example, a photoresist layer (not shown) is applied over the dummy gate electrode layer and lithographically patterned by lithographic exposure and development. The pattern in the photoresist layer is sequentially transferred into the dummy gate electrode layer and the dummy gate dielectric layer by at least one anisotropic etching process, thereby forming the dummy gate stack (222, 224), which comprises the remaining portions of the dummy gate dielectric layer and the dummy gate electrode layer. The anisotropic etching process may be a dry etching process, for example, RIE, a wet etching process, or a combination thereof. If not completely consumed, the remaining photoresist layer after formation of the dummy gate stack (222, 224) is removed by, for example, ashing.

The gate spacers 226 are disposed on sidewalls of the dummy gate stack (222, 224). In some embodiments, the gate spacers 226 may include a dielectric material such as, for example, an oxide, a nitride, an oxynitride, or combinations thereof. In some embodiments, the gate spacers 226 are made of silicon nitride. In some embodiments, the gate spacers 226 may be formed by first depositing a conformal gate spacer material layer on exposed surfaces of the dummy gate stack (222, 224), the hard mask portion 209P, the fin-shaped structure 210, and the isolation features 216 and then etching the gate spacer material layer to remove horizontal portions of the gate spacer material layer. In some embodiments, the gate spacer material layer may be deposited, for example, by CVD, PECVD, or ALD. In some embodiments, the gate spacer material layer may be etched by dry etch such as, for example, plasma etching or RIE. Vertical portions of the gate spacer material layer present on the sidewalls of the dummy gate stack (222, 224) constitute the gate spacers 226.

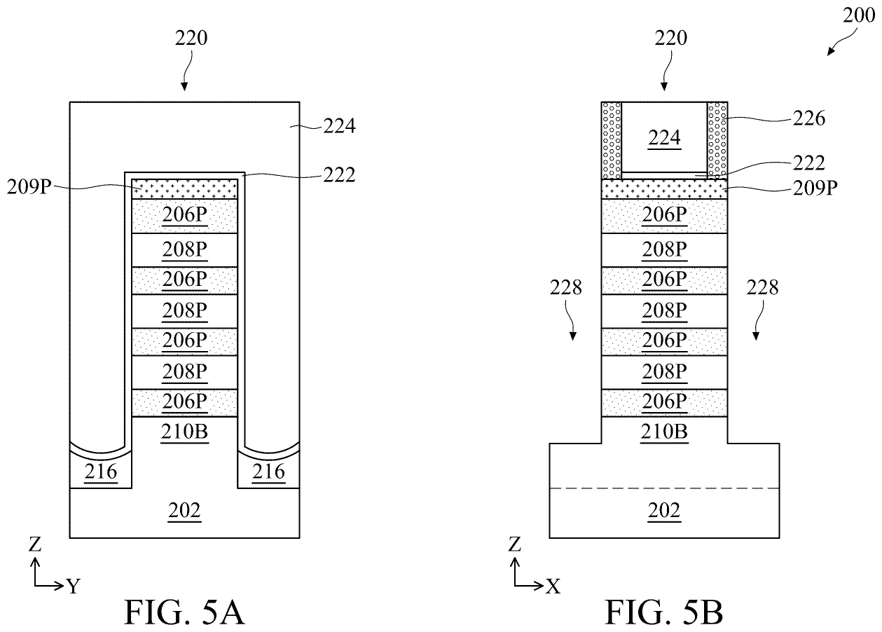

Referring to FIGS. 1 and 5A-5B, the method 100 proceeds to operation 108, where source/drain trenches 228 are formed in the fin-shaped structure 210, in accordance with some embodiments. FIGS. 5A and 5B are cross-sectional views of the GAA device 200 after forming the source/drain trenches 228.

In some embodiments, the hard mask portion 209P, the sacrificial semiconductor portions 206P, and the channel semiconductor portions 208P in the source/drain regions are etched using the dummy gate structure 220 as an etch mask to form the source/drain trenches 228. The etching may be performed by a dry etching process such as plasma etching or RIE. An example dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. Alternatively, the etching may be performed by a wet etching process that uses an etchant such as a mixture of ammonium hydroxide, hydrogen peroxide, and water (APM), tetramethylammonium hydroxide (TMAH), or ammonium hydroxide (NH₄OH). As shown in FIG. 5B, sidewalls of the hard mask portions 209P, the sacrificial semiconductor portions 206P, and the channel semiconductor portions 208P are exposed in the source/drain trenches 228. In some embodiments, the substrate 202 may also be partially etched. Accordingly, the bottom surfaces of the source/drain trenches 228 may be leveled with the top surface of the base portion 210B or lower than the top surface of the base portion 210B.

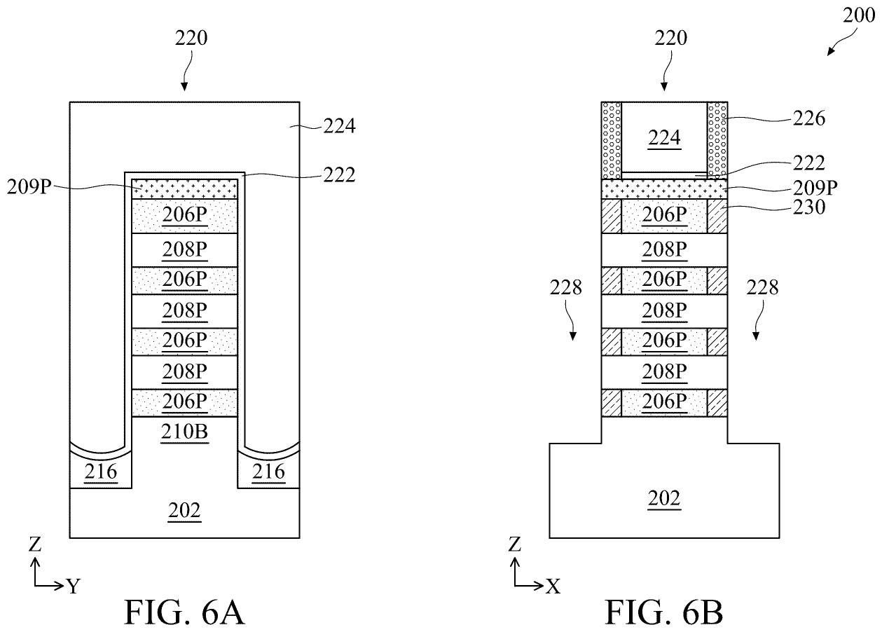

Referring to FIGS. 1 and 6A-6B, the method 100 proceeds to operation 110, wherein inner spacers 230 are formed, in accordance with some embodiments. FIGS. 6A and 6B are cross-sectional views of the GAA device 200 after forming the inner spacers 230.

In some embodiments and as shown in FIG. 6B, the inner spacers 230 have generally the same lateral dimensions as the gate spacers 226 and contact sidewalls of the sacrificial semiconductor portions 206P. At operation 110, the sacrificial semiconductor portions 206P exposed in the source/drain trenches 228 are laterally recessed to form inner spacer recesses in the fin stack portion 210S of the fin-shaped structure 210. In some embodiments, the lateral etching process may be performed using an isotropic etching process that etches the semiconductor material (e.g. SiGe) of the sacrificial semiconductor portions 206P in the fin-shaped structure 210 selective to the semiconductor material (e.g., Si) of the channel semiconductor portions 208P, and other exposed elements. In some embodiments, the amount of the sacrificial semiconductor portions 206P etched is controlled so that the lateral etching distance is no greater than the width of the gate spacers 226. In some embodiments, an isotropic wet etching process may be performed using an etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, lateral ends of the sacrificial semiconductor portions 206P that are exposed in the source/drain trenches 228 may be first selectively oxidized to increase the etching selectivity between the sacrificial semiconductor portions 206P and the channel semiconductor portions 208P. In some embodiments, the oxidation process may be performed by exposing the structure to a wet oxidation process, a dry oxidation process, or a combination thereof.

After the formation of the inner spacer recesses, an inner spacer material layer is deposited over the structure including in the inner spacer recesses. The inner spacer material layer may include silicon oxide, silicon nitride, silicon oxycarbide, silicon oxycarbonitride, silicon carbonitride, metal nitride, or any suitable dielectric material. The inner spacer material layer may be formed by CVD, ALD or any other suitable conformal deposition processes. In some embodiments, the inner spacer material layer may be formed to have a thickness such that the inner spacer recesses are completely filled by the inner spacer material layer.

An etching process, such as an anisotropic etching process, is then performed to remove portions of the inner spacer material layer disposed outside the inner spacer recesses in the fin-shaped structure 210. The remaining portions of the inner spacer material layer (i.e., portions disposed inside the inner spacer recesses) form the inner spacers 230. In some embodiments, the anisotropic etching process may be a wet etching process that includes use of an etchant such as, for example, buffered hydrofluoric acid (BHF), hydrofluoric acid (HF), hydrofluoric nitric acid (HNA), phosphoric acid, HF diluted by ethylene glycol (HFEG), hydrochloric acid (HCl), or any combination thereof. In some embodiments, the anisotropic etching process may be a dry etching process that includes use of an oxygen-containing gas, hydrogen, nitrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof.

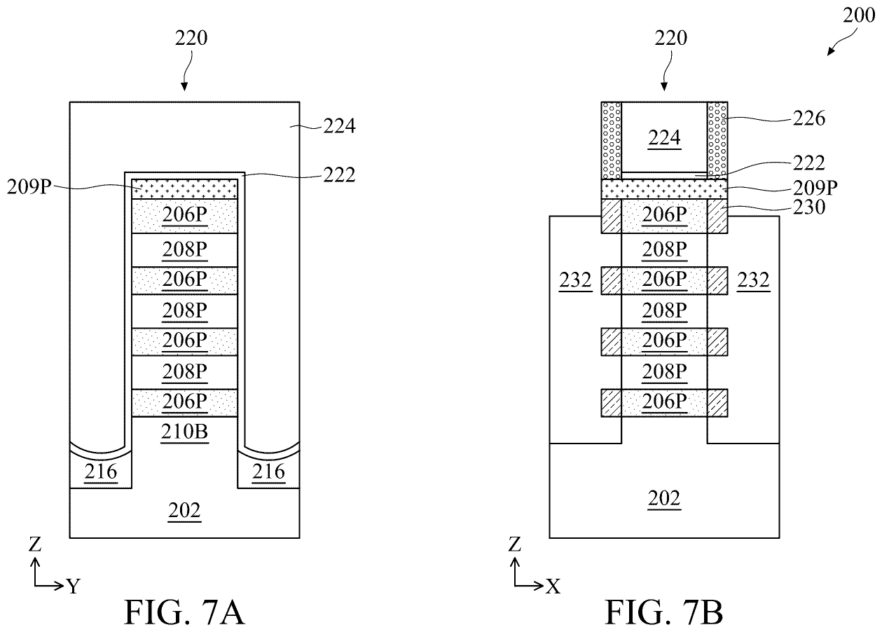

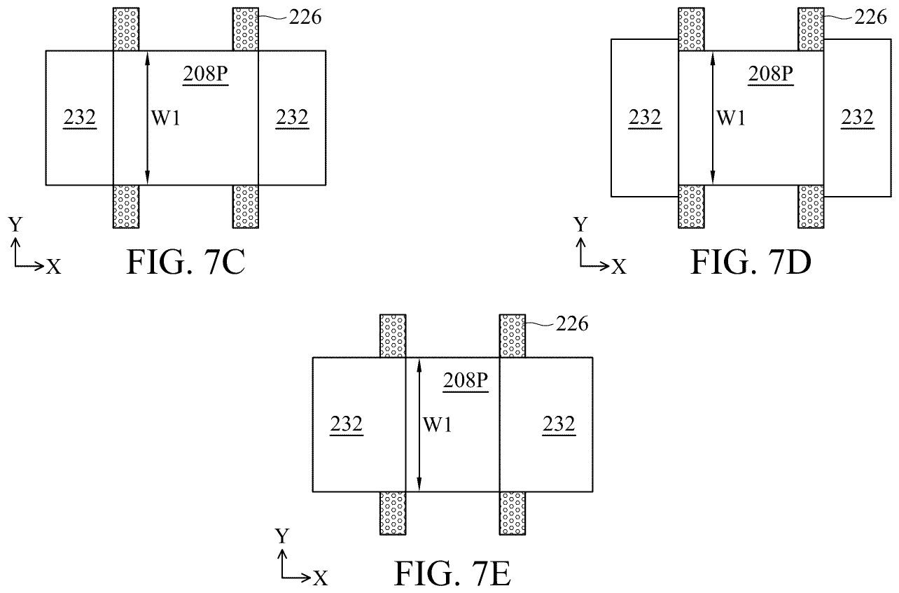

Referring to FIGS. 1 and 7A-7B, the method 100 proceeds to operation 112, where source/drain features 232 are formed in the source/drain trenches 228, in accordance with some embodiments. FIGS. 7A and 7B are cross-sectional views of the GAA device 200 after forming the source/drain features 232. The source/drain features 232 are disposed on opposite sides of the dummy gate structure 220, the sacrificial semiconductor portions 206P, and the channel semiconductor portions 208P such that the source/drain features 232 are in contact with the channel semiconductor portions 208P but are separated from the sacrificial semiconductor portions 206P by the inner spacers 230.

The source/drain features 232 are epitaxially grown in the source/drain trenches 228. The epitaxy process may include CVD deposition (for example, vapor-phase epitaxy (VPE) ultra-high vacuum CVD (UHV-CVD), low pressure CVD (LPCVD), plasma-enhanced CVD (PECVD)), molecular beam epitaxy (MBE), other suitable selective epitaxy growth (SEG) processes, or combinations thereof. Due to the fact that the substrate 202 in the source/drain trenches 228 is covered by the isolation feature 216, there is no nucleation site at the bottom during the source/drain epitaxy growth. As a result, the source/drain features 232 grow laterally from the exposed sidewalls of the channel semiconductor portions 208P and the base portion 210B in the fin-shaped structure 210.

The source/drain features 232 may include any suitable material for n-type or p-type FET devices. For example, when n-type FET devices are formed, the source/drain features 232 may include materials exerting a tensile strain in the channel regions, such as Si, SiC, SiCP, SiP, or the like, and may be in-situ doped during the epitaxy process by introducing an n-type dopant, such as phosphorus (P), arsenic (As), or ex-situ doped using an implantation process (i.e., a junction implant process). Likewise, when p-type FET devices are formed, the source/drain features 232 may include materials exerting a compressive strain in the channel regions, such as Si, SiGe, SiGeB, Ge, GeSn, or the like and may be in-situ doped during the epitaxy process by introducing a p-type dopant, such as boron (B), aluminum (Al), gallium (Ga), and indium (In), or ex-situ doped using an implantation process (i.e., a junction implant process). The epitaxial source/drain features 232 may have surfaces raised from respective surfaces of the channel semiconductor portions 208P and may have facets. In some embodiments, the source/drain features 232 are p-type source/drain features and include boron-doped SiGe. In some embodiments, the source/drain features 232 are n-type source/drain features and include phosphorus-doped Si.

FIGS. 7C-7E are plan views of the channel and source/drain regions along the X-Y plane. Referring to FIG. 7C, in some embodiments, the epitaxy growth of the source/drain features 232 is controlled so that the lateral epitaxy growth forms source/drain features 232 having the same width as the channel semiconductor portions 208P. As shown in FIG. 7C, sidewalls of the source/drain features 232 are aligned with sidewalls of the channel semiconductor portions 208P along the Y-direction. Referring to FIG. 7D, in some other embodiments, the lateral epitaxy growth forms source/drain features 232 having a width greater than that of the channel semiconductor portions 208P. In such instances, sidewalls of the source/drain features 232 expand laterally outward beyond the sidewalls of the channel semiconductor portions 208P along the Y-direction, as shown in FIG. 7D.

In some embodiments, a thermal anneal process is performed following the epitaxial growth and doping of the source/drain features 232. This process causes dopants to be injected into portions of the channel semiconductor portions 208P that are in contact with the source/drain features 232. This anneal process effectively extends the source/drain features 232 into the end portions of the channel semiconductor portions 208P, reducing parasitic resistance of the nanosheet FET devices. In other embodiments, the thermal anneal process is performed in a later process (such as after the formation of the high-k gate dielectric layers) so that the same anneal process can serve two purposes at the same time: driving dopants into the channel semiconductor portions 208P, and improving the reliability of the high-k gate dielectric. In some embodiments and as shown in FIGS. 7B and 7E, after annealing, sidewalls of the source/drain features 232 are aligned with the inner sidewalls of the gate spacers 226. In some other embodiments, the thermal anneal process is omitted, and the sidewall of the source/drain features 232 are aligned with the outer sidewalls of the gate spacers 226 (FIGS. 7C and 7D).

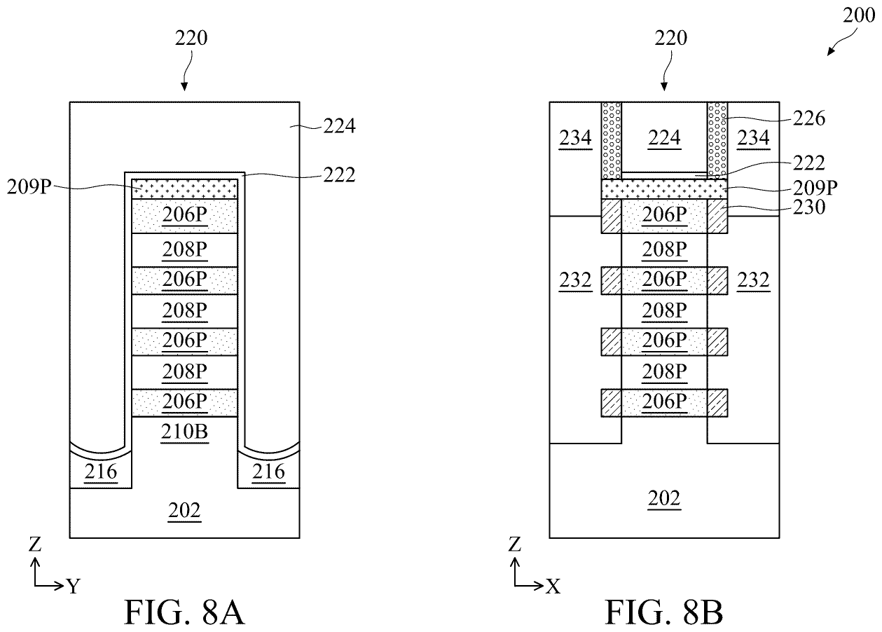

Referring to FIGS. 1 and 8A-8B, the method 100 proceeds to operation 114, where an interlayer dielectric (ILD) layer 234 is formed over the source/drain features 232 and the isolation feature 216, in accordance with some embodiments. FIGS. 8A and 8B are cross-sectional views of the GAA device 200 after forming the ILD layer 234.

In some embodiments, the ILD layer 234 may include a low-k dielectric material having a dielectric constant lower than the dielectric constant (about 3.9) of silicon dioxide. The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOₓC_{y}), spin-on-glass (SOG), or combinations thereof. The ILD layer 234 may include a multi-layer structure having multiple dielectric materials and may be formed by CVD, flowable CVD (FCVD), spin coating, or other suitable deposition processes. In some embodiments, forming the ILD layer 234 further includes performing a CMP process to planarize a top surface of the ILD layer 234, such that the dummy gate electrode 224 is exposed. The top surface of the ILD layer 234 may be coplanar with the top surfaces of the dummy gate electrode 224 and the gate spacers 226.

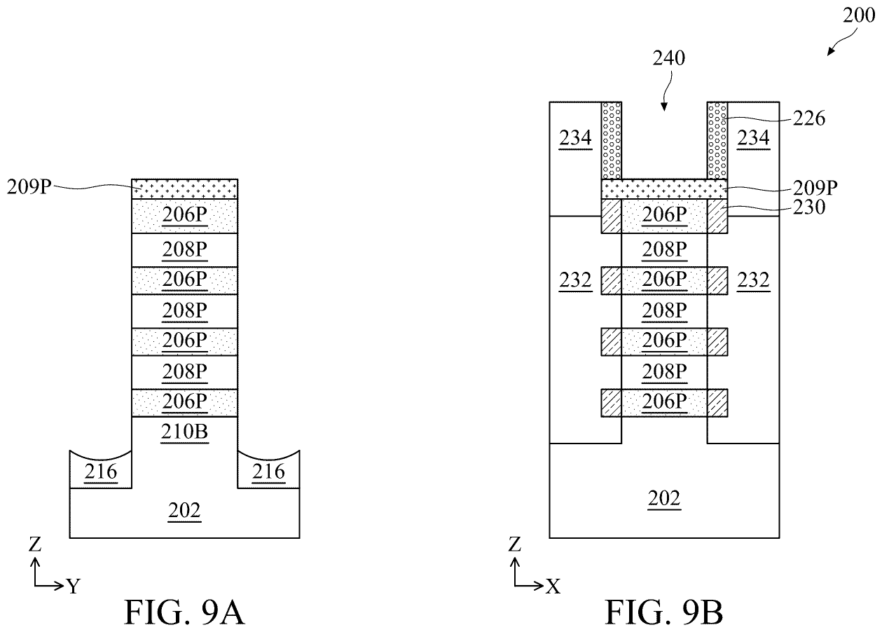

Referring to FIGS. 1 and 9A-9B, the method 100 proceed to operation 116, where the dummy gate stack (222, 224) including the dummy gate dielectric 222 and the dummy gate electrode 224 are removed, in accordance with some embodiments. FIG. 9A and 9B are cross-sectional views of the GAA device 200 after removing the dummy gate stack (222, 224).

An etching process selectively removes the dummy gate dielectric 222 and the dummy gate electrode 224, thereby forming a gate trench 240 that exposes the hard mask portion 209P, the sacrificial semiconductor portions 206P, and the channel semiconductor portions 208P in the channel region of the fin-shaped structure 210. The ILD layer 234 protects the source/drain features 232 during the etching process. The etching process may be a dry etching process, a wet etching process, or a combination thereof. The etching process can be tuned such that the dummy gate dielectric 222 and the dummy gate electrode 224 are removed without (or minimally) etching other elements in the GAA device 200, including the ILD layer 234, the source/drain features 232, the gate spacers 226, and the hard mask portion 209P. For example, in instances where the dummy gate electrode 224 is composed of polysilicon and the ILD layer 234 is composed of silicon oxide, a wet etchant such as a TMAH solution may be used to selectively remove the dummy gate electrode 224. The dummy gate dielectric 222 is thereafter removed using plasma dry etching and/or wet etching.

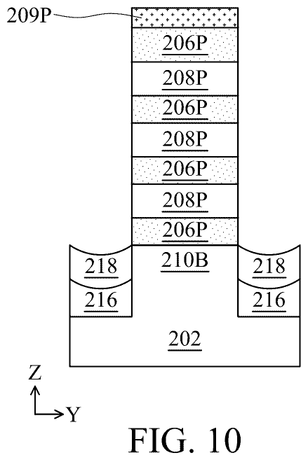

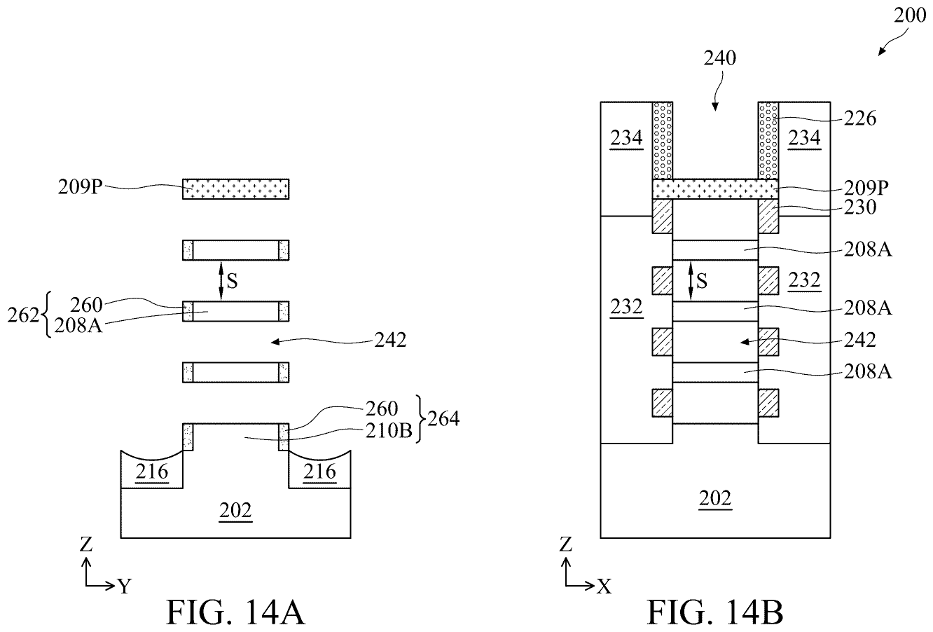

In some embodiments, after removing the dummy gate stack (222, 224), a base mask layer 218 may be formed on the isolation feature 216 to surround the exposed portion of the base portion 210B above the isolation feature 216 (FIG. 10). The base mask layer 218 prevents the subsequent epitaxial growth of semiconductor material from the base portion 210B. As a result, a semiconductor cap (260 of FIG. 14A) will not be formed on the base portion 210B, thereby preventing the increase in I_{off} caused by the bottom planar transistor. The formation of the base mask layer 218 is optional.

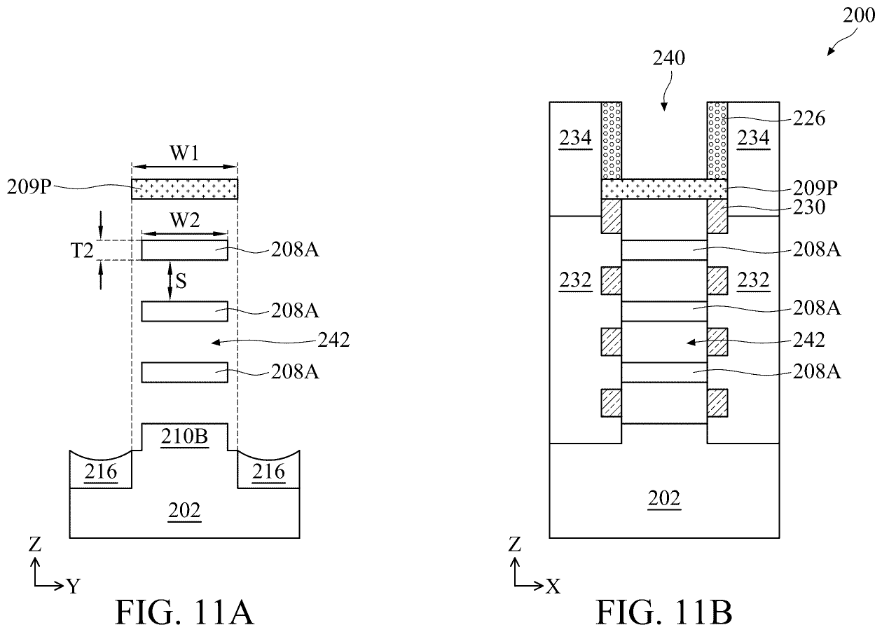

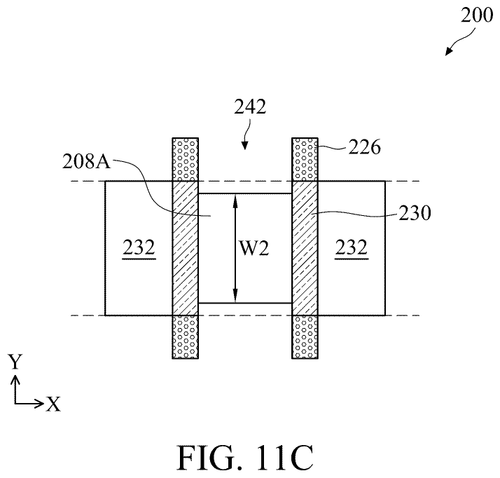

Referring to FIGS. 1 and 11A-11B, the method 100 proceeds to operation 118, where the sacrificial semiconductor portions 206P are removed, in accordance with some embodiments. FIGS. 11A and 11B are cross-sectional views of the GAA device 200 after removing the sacrificial semiconductor portions 206P.

The selective removal of the sacrificial semiconductor portions 206P releases the channel semiconductor portions 208P to form channel members 208A. In some embodiments, the channel members 208A are nanosheets. In some embodiments, the sacrificial semiconductor portions 206P may be removed by a selective etching process using an etchant that is selective to the material of sacrificial semiconductor portions 206P, such that the sacrificial semiconductor portions 206P are removed without substantially attacking the channel semiconductor portions 208P. In some embodiments, the etching process is an isotropic etching process which can be a dry etching process or a wet etching process. In some embodiments, the selective etching process may include oxidizing the sacrificial semiconductor portions 206P using a suitable oxidizer, such as ozone. Thereafter, the oxidized sacrificial semiconductor portions 206P may be selectively removed. In some embodiments, when the channel semiconductor portions 208P include Si and the sacrificial semiconductor portions 206P include SiGe, the sacrificial semiconductor portions 206P may be selectively removed by applying an HCl gas at a temperature of about 500° C. to about 700° C., or applying a gas mixture of CF₄, SF₆, and CHF₃. The inner spacers 230 serve as etch stop layers to protect the source/drain features 232 during removal of the sacrificial semiconductor portions 206P. After the removal of the sacrificial semiconductor portions 206P, the channel semiconductor portions 208P form a plurality of channel members 208A.

In some embodiments, after exposing the channel members 208A by removing the sacrificial semiconductor portions 206P, a trimming operation may be performed to reduce the thickness of the channel members 208A, thereby improving the gate fill window. The trimming operation can utilize any suitable etching process, such as dry etching, wet etching, or a combination of both. Following the trimming operation, the channel members 208A may have a width W2 ranging from about 10 nm to about 90 nm, for example, from about 10 nm to about 40 nm, and a thickness T2 ranging from about 4 nm to about 7 nm.

As shown in FIGS. 11A and 11B, gaps 242 (e.g., empties spaces) are formed between adjacent channel members 208A, between the topmost channel member 208A and the hard mask layer 209, and between the bottommost channel member 208A and the base portion 210B, as a result of the removal of the sacrificial semiconductor portions 206P and nanosheet trimming. The gaps 242 define the spacing S between adjacent channel members 208A. In some embodiments, the spacing between the adjacent channel members 208A (also referred to as sheet-to-sheet spacing) may range from about 8 nm to about 15 nm.

However, the etching processes used to remove the sacrificial semiconductor portions 206P and to trim the channel members 208A also recess the channel members 208A along the Y direction, causing a width loss in the channel members 208A. This width loss leads to dumbbell-shaped channel members 208A. FIG. 11C is a plan view of the channel and source/drain regions along the X-Y plane. As shown in FIG. 11C, the channel width loss causes the sidewalls of the channel member 208A to be recessed from the sidewalls of the inner spacers 230 along the Y direction. The channel members 208A have a width W2 smaller than the width W1 of the hard mask portion 209P (i.e., the width of the channel semiconductor portions 208P) (FIG. 11A). In some embodiments, the width W1 of channel semiconductor portions 208P in the channel region of the fin-shaped structure 210 may range from 12.5 nm to 45 nm, and after the nanosheet formation and nanosheet trimming processes, the width W2 of the channel members 208A may be reduced to 10 nm to 40 nm.

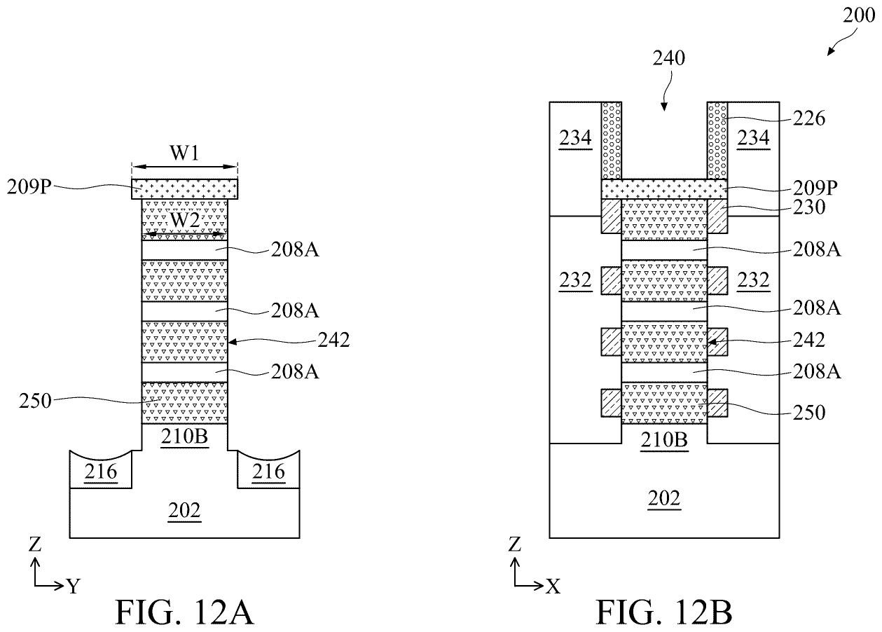

Referring to FIGS. 1 and 12A-12B, the method 100 proceeds to operation 120, where sacrificial plugs 250 are formed to fill the gaps 242, in accordance with some embodiments. FIGS. 12A and 12B are cross-sectional views of the GAA device 200 after forming the sacrificial plugs 250 to fill the gaps 242.

A sacrificial material layer is conformally deposited on the channel members 208A and the hard mask portion 209P exposed by the gate trench 240 and the gaps 242. In some embodiments, the thickness of the sacrificial material layer is controlled such that portions of the sacrificial material layer in the gaps 242 are merged. Accordingly, the sacrificial material layer fully fills the gaps 242. The sacrificial material layer may include a material that can be selectively etched related to the hard mask portion 209P. In some embodiments, the sacrificial material layer may include a metal oxide such as aluminum oxide (AlOₓ), or zirconium oxide. The sacrificial material layer may be formed by a suitable deposition process such as PVD, CVD, ALD, or other suitable conformal deposition methods. Next, an etching process, such as an anisotropic etching process, is performed to remove portions of the sacrificial material layer disposed outside the gaps 242 from the structure. The remaining portions of the sacrificial material layer remain in the gaps 242 form the sacrificial plugs 250.

Referring to FIGS. 1 and 13A-13B, the method proceeds to operation 122, where semiconductor caps 260 are on opposite sidewalls of the channel members 208A and the base portion 210B, in accordance with some embodiments. FIGS. 13A-13B are cross-sectional views of the GAA device 200 after forming the semiconductor caps 260 on the opposite sidewalls of the channel members 208A and the base portion 210B. Each channel member 208A, along with its corresponding semiconductor caps 260 on the sidewalls constitutes a channel nanostructure 262. The base portion 210B, along with the semiconductor caps 260 on its sidewall constitutes a mesa structure 264.

The semiconductor caps 260 are incorporated to offset the width reduction that occurs during the formation of the channel members 208A. In some embodiments, the material of semiconductor caps 260 is elected so that no significant difference in chemical or material properties exists between the semiconductor caps 260 and the channel members 208A. In some embodiments, the semiconductor caps 260 are composed of the same semiconductor material as the channel members 208A. For instance, in some embodiments, where the channel members 208A are made of Si, the semiconductor caps 260 are also composed Si. Interfaces may exist between the channel members 208A and their respective semiconductor caps 260, or there may be no interfaces therebetween.

The semiconductor caps 260 may be formed by epitaxy growth, during which the semiconductor caps 260 are epitaxially grown from semiconductor surfaces, including sidewalls of the channel members 208A and the base portion 210B, but not from the dielectric surfaces, such as surfaces of the hard mask portion 209P, the gate spacers 226, the inner spacers 230, the ILD layer 234, and the sacrificial plug 250. Accordingly, the semiconductor caps 260 are only grown on opposite sidewalls of the channel members 208A and the base portion 210B along the Y-direction, while the epitaxial growth of the semiconductor caps 260 on the top and bottom surfaces of the channel members 208A and the top surface of the base portion 210B are blocked by the hard mask portion 209P and the sacrificial plugs 250.

The thickness of the semiconductor caps 260 is controlled by the duration of the epitaxy growth process. The semiconductor caps 260 may formed with various thicknesses. FIGS. 13C-13F are plan views of the channel and source/drain regions illustrating different thicknesses of semiconductor caps 260 formed by the epitaxy growth, in accordance with some embodiments. In some embodiments and as shown in FIG. 13C, the semiconductor caps 260 are formed to match the width lost by the channel members 208A during the sheet formation process. Consequently, the semiconductor caps 260 have sidewalls aligned with the sidewalls of the inner spacers 230 in the Y-direction. The sidewalls may be curved or straight. In some other embodiments and as shown in FIG. 13D, the semiconductor caps 260 are formed to have a thickness less than the width lost by the channel members 208A during the sheet formation process. As a result, the semiconductor caps 260 exhibit a dumbbell-shaped with recessed sidewalls relative to the sidewalls of the inner spacers 230 in the Y-direction. In still some other embodiments and as shown in FIGS. 13E and 13F, the semiconductor caps 260 are formed with a thickness greater than the width lost by the channel members 208A during the sheet formation process, causing the sidewalls of the semiconductor caps 260 to protrude beyond the sidewalls of inner spacers 230 in the Y-direction. In some embodiments, each protruding portion of the semiconductor caps 260 has a flat surface, as illustrated in FIG. 13E. In other embodiments, as shown in FIG. 13F, each protruding portion of the semiconductor caps 260 may have a curved surface due to the semiconductor material not growing on the dielectric surfaces of the gate spacers 226. In some embodiments, each protruding portion of the semiconductor caps 260 may have a thickness D1 less than 5 nm.

The thickness of the semiconductor caps 260 on the sidewalls of the channel members 208A may be the same or different from the thickness of the semiconductor caps 260 on the sidewalls of the base portion 210B. As shown in FIG. 13A, in instances where the height of the base portion 210B is the same as the thickness of the channel members 208A, the thickness T3′ of the semiconductor caps 260 on the base portion 210B is the same as the thickness T3 of the semiconductor caps 260 on the channel members 208A. However, as shown in FIG. 13G, in instances where the height of the base portion 210B is greater than the thickness of the channel members 208A, the thickness T3′ of the semiconductor caps 260 on the base portion 210B exceeds the thickness T3 of the semiconductor caps 260 on the channel members 208B due to the additional surface area available for epitaxial growth.

Referring to FIGS. 1 and 14A-14B, the method 100 proceeds to operation 124, where the sacrificial plugs 250 are removed, in accordance with some embodiments. FIGS. 14A and 14B are cross-sectional views of the GAA device 200 after removing the sacrificial plugs 250.

The sacrificial plugs 250 may be removed by an isotropic etching process. The isotropic etching process may be a dry etching process such as RIE or a wet etching process that etches the sacrificial plugs 250 selective to the channel members 208A, the base portion 210B, the semiconductor caps 260, and the hard mask portion 209P. After removing the sacrificial plugs 250, the gaps 242 reappear, exposing the top and bottom surfaces of the channel members 208A and the top surface of the base portion 210B in the Z-direction.

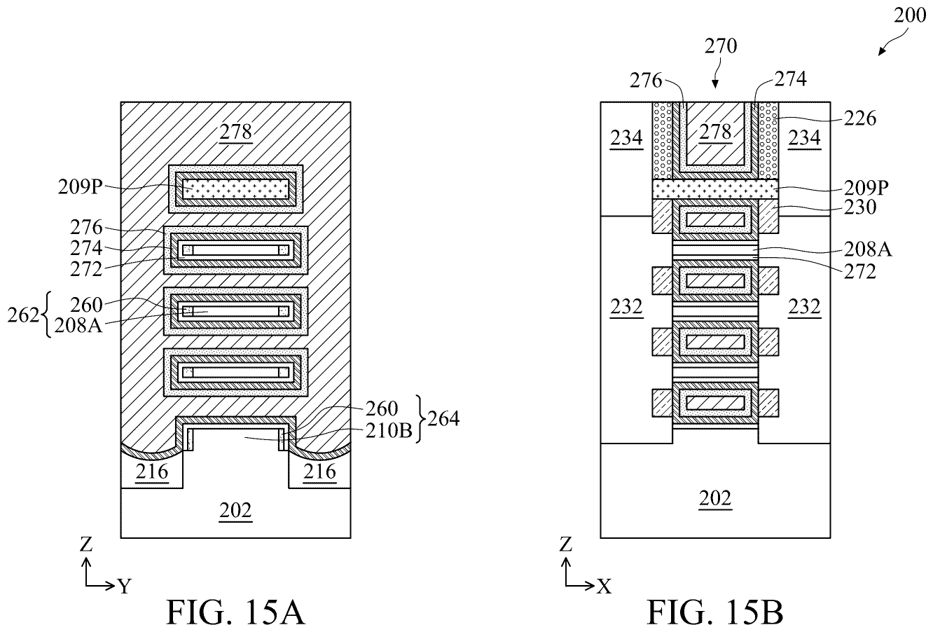

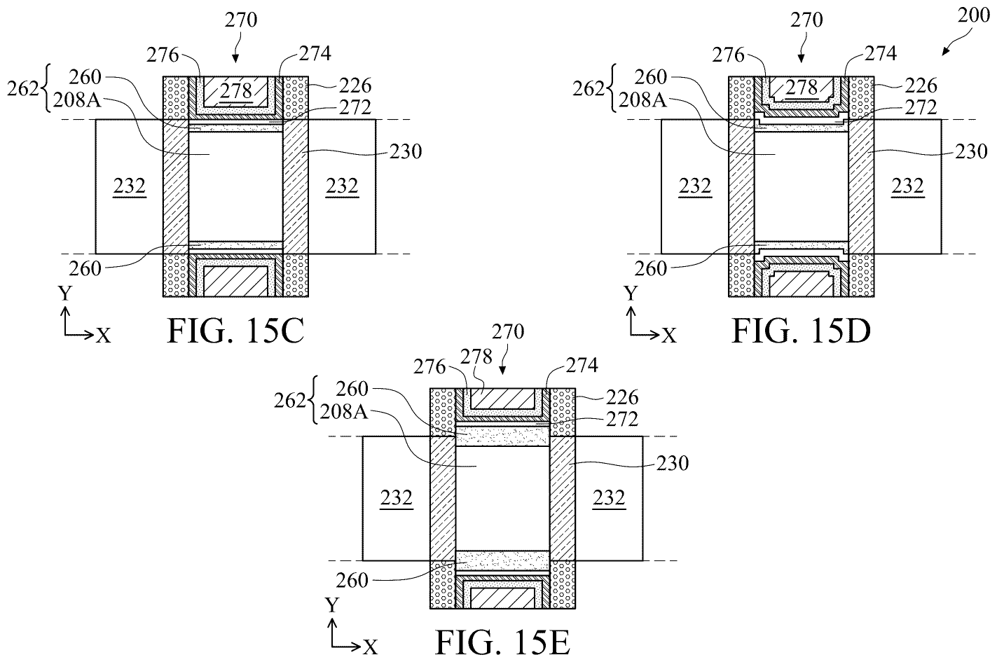

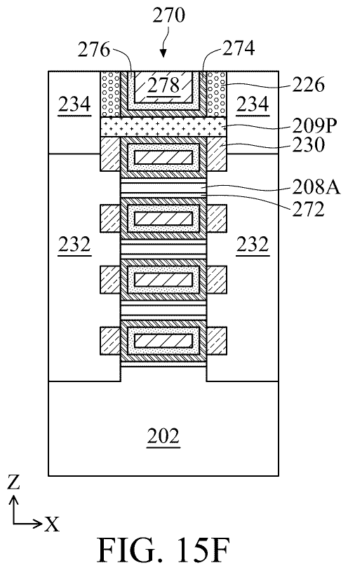

Referring to FIGS. 1 and 15A-15B, the method 100 proceeds to operation 126, where a gate stack 270 is formed in the gate trench 240 and the gaps 242, in accordance with some embodiments. FIGS. 15A and 15B are cross-sectional views of the GAA device 200 after forming the gate stack 270. The gate stack 270 is deposed over and between the channel nanostructures 262, respectively and over the mesa structure 264. In some embodiments, the gate stack 270 includes an interfacial layer 272, a gate dielectric layer 274, a work function layer 276, and a gate electrode layer 278.

The interfacial layer 272 is formed on the exposed surfaces of the channel nanostructures 262 and the mesa structure 264. The interfacial layer 272 promotes adhesion of the gate dielectric layer 274 to the channel nanostructures 262. In some embodiments, the interfacial layer 272 may include a dielectric material such as silicon oxide. In some embodiments, the interfacial layer 272 may be formed by chemical oxidation or thermal oxidation of surface portions of the channel nanostructures 262 and the mesa structure 264. For example, in some embodiments, the interfacial layer 272 is formed using an ozonated deionized water comprising ozone. The thickness of the interfacial layer 272 ranges from about 0.5 nm to about 1.5 nm. In some embodiments, the interfacial layer 272 is about 1 nm thick, achieved by oxidizing around 1 nm of the channel nanostructures 262. FIGS. 15C-15E are plan views of the channel and source/drain regions illustrating the interfacial layer 272 formed in the semiconductor caps 260. In instances where the channel nanostructures 262 have the sidewalls aligned with the sidewalls of the inner spacers 230, the interfacial layer 272 extends between the inner spacers 230 in the X-direction and has sidewalls aligned with the sidewalls of the inner spacers 230 in the Y-direction, as shown in FIG. 15C. When the channel nanostructures 262 are dumbbell-shaped, the interfacial layer 272 is U-shaped, laterally surrounding the gate dielectric layer 274, as shown in FIG. 15D. If the channel nanostructures 262 protrude beyond the sidewalls of inner spacers 230 in the Y-direction, the interfacial layer 272 extends between the gate spacers 226 in the X-direction, with sidewalls contacting the gate spacers 226, as depicted in FIG. 15E.

Afterwards, the gate dielectric layer 274 is conformally deposited over the interfacial layer 272 and the hard mask portion 209P. The gate dielectric layer 274 wraps around the channel nanostructures 262 and the hard mask portion 209P, and is on the sidewalls of the gate trench 240. In some embodiments, the gate dielectric layer 274 may include a high-k dielectric material having a dielectric constant greater than silicon dioxide. Examples of high-k dielectric materials include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), titanium oxide (TiO₂), and hafnium oxide-alumina (HfO₂—Al₂O₃) alloy. The gate dielectric layer 274 may be formed by CVD, ALD or other suitable conformal deposition methods. In some embodiments, the gate dielectric layer 274 is formed using a conformal deposition process such as ALD in order to ensure that the high-k gate dielectric layer 274 has a uniform thickness around each of channel nanostructures 262. The gate dielectric layer 274 may be formed to have a thickness ranging from about 1 nm to about 2.5 nm. In some embodiments, the gate dielectric layer 274 may be formed to have a thickness of about 1.5 nm.

Subsequently, a work function layer 276 is deposited over the gate dielectric layer 274. For an n-type FET, the work function layer 276 may include an n-type work function layer adapted to tune the threshold voltage for n-type FET. Suitable n-type work function materials include, but are not limited to, aluminum (Al), titanium aluminum (TiAl), titanium aluminum carbide (TiAlC), tantalum aluminum carbide (TaAlC), tantalum aluminum silicide (TaSiAl), tantalum silicon carbide (TaSiC), tantalum silicide (TaSi), hafnium carbide (HfC), and combinations thereof. For a p-type FET, the work function layer 276 may include a p-type work function layer adapted to tune the threshold voltage for p-type FET. In some embodiments, the p-type work function layer includes tungsten (W), molybdenum (Mo), tungsten nitride (WN), tungsten carbon nitride (WCN), tantalum silicon nitride (TaSiN), or tantalum nitride (TaN). The work function layer may be formed by a conformal deposition process such as, for example, ALD or CVD. In some embodiments, the work function layer 276 may be formed to have a thickness ranging from about 1.5 nm to about 2.5 nm.

Afterwards, the gate electrode layer 278 is formed on the work function layer 276 to fill any remaining volumes in the gate trench 240 and the gaps 242. The gate electrode layer 278 may include a conductive material such as tungsten, cobalt, ruthenium, iridium, molybdenum, copper, aluminum, or combinations thereof. The gate electrode layer 278 may be formed by any suitable deposition process such as CVD, PECVD, PVD, or electrochemical plating.

Next, excess portions of the gate dielectric layer 274, the work function layer 276, and the gate electrode layer 278 that are deposited on the top surface of the ILD layer 234 and the gate spacers 226 are removed in a planarization process such as a CMP process to form the gate stack 270. The top surface of the gate stack 270 may be coplanar with the top surfaces of the ILD layer 234 and the gate spacers 226. In some embodiments and as shown in FIG. 15F, some portions of the gate spacers 226 and ILD layer 234 are also removed in the CMP process to reduce the thickness of the gate electrode layer 278 over the hard mask portion 209P, thereby helping to reduce RC delay.

The gate stack 270 thus formed surrounds the channel nanostructures 262 and fills the gaps 242 between the channel nanostructures 262, the gap 242 between the hard mask portion 209P and the topmost channel nanostructure 262, and the gap 242 between the bottommost channel nanostructure 262 and the mesa structure 264. Between the channel nanostructures 262, the gate electrode layer 278 is circumferentially surrounded (in the cross-sectional view) by the work function layer 276, which is then circumferentially surrounded by the gate dielectric layer 274. In the portion of the gate stack 270 formed over the hard mask portion 209P, the gate electrode layer 278 is formed over the work function layer 276 with the work function layer 276 wrapping around the gate electrode layer 278 and the gate dielectric layer 274 wrapping around the work function layer 276.

Additional processing may be performed to finish the fabrication of the GAA device 200. For example, gate contact (not illustrated for simplicity) and the source/drain contacts may be formed to electrically couple to the gate stack 270 and the source/drain features 232, respectively. An interconnect structure may then be formed over the source/drain contacts and the gate contact. The interconnect structure may include a plurality of dielectric layers surrounding metallic features, including conductive traces and conductive vias, which form electrical connection between devices on the substrate 202, such as the GAA device 200.

The embodiments of the present disclosure provide advantages. By incorporating semiconductor caps to compensate for the sheet width loss, the dumbbell-shaped channel profile can be improved from over 2 nm to 1 nm or less, or completely eliminated. This increase in channel width helps to reduce overlapping area between the source/drain features and the metal gate, thereby reducing parasitic capacitance. Additionally, the channel width increase enhances current flow. As a result, the device performance can be increased.

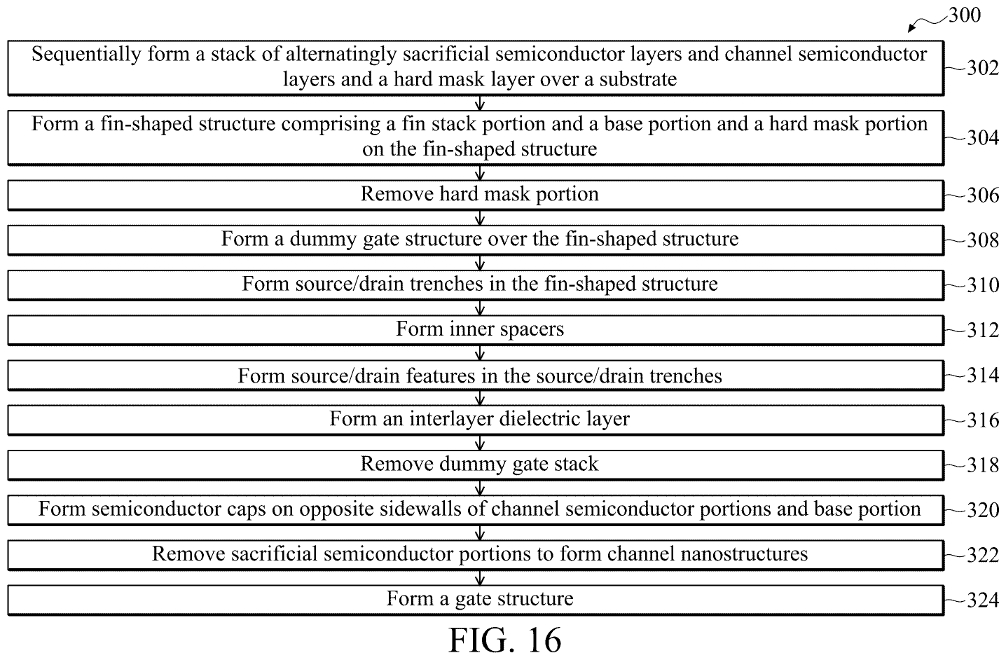

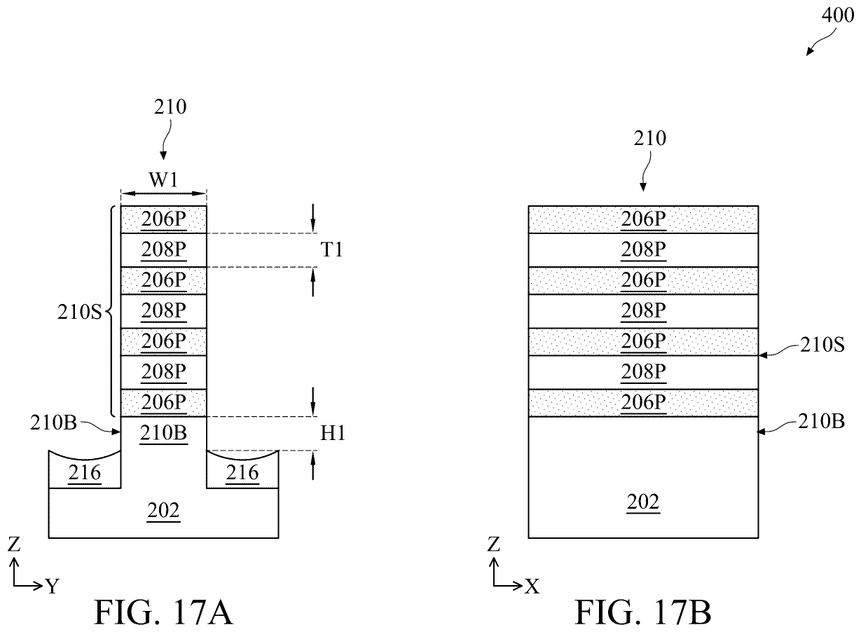

FIG. 16 is a flowchart of a method 300 of forming a GAA device 400, in accordance with some embodiments of the present disclosure. FIGS. 17A-27D are various views of the GAA device 400 at various stages of the method 300, in accordance with some embodiments. Some embodiments of method 300 are described below in conjunction with FIGS. 17A-27D with reference to the GAA device 400. The method 300 is merely an example and is not intended to limit the present disclosure beyond what is explicitly recited in the claims.

Additional operations can be provided before, during, and after the method 300, and some operations described can be replaced, eliminated, or moved around for additional embodiments of the method.

At operation 302, the method 300 forms an initial structure of the GAA device 400. This initial structure includes a substrate 202, a stack 204 of alternating sacrificial semiconductor layers 206 and channel semiconductor layers 208 over the substrate 202, and a hard mask layer 209 over the topmost surface of the stack 204. This initial structure is illustrated in FIG. 2, and the operation has been discussed above with reference to FIG. 2.

Referring to FIG. 16, the method 300 proceeds to operation 304, where a fin-shaped structure 210 is formed from the stack 204, in accordance with some embodiments. This operation has been described above with reference to FIGS. 1 and 3A-3B.

Referring to FIGS. 16 and 17A-17B, the method 300 proceeds to operation 306, where the hard mask portion 209P is removed, in accordance with some embodiments. FIGS. 17A and 17B are cross-sectional views of the GAA device 400 after removing hard mask portion 209P.

The hard mask portion 209P is removed from the topmost surface of the fin-shaped structure 210. The removal of the hard mask portion 209P may be performed using an anisotropic etching process. The etching process may be a dry etching process such as RIE, a wet etching process, or a combination thereof.

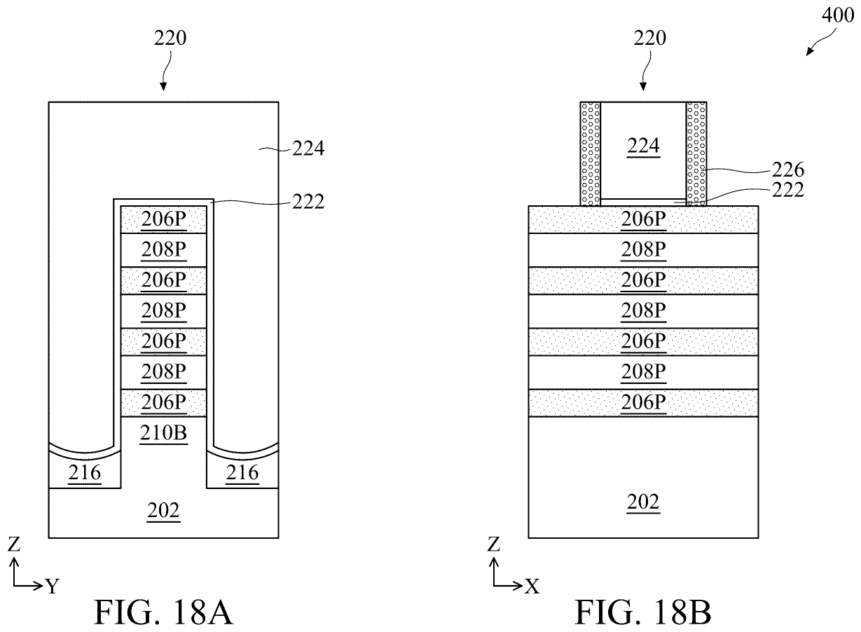

Referring to FIGS. 16 and 18A-18B, the method 300 proceeds to operation 308, where a dummy gate structure 220 is formed over the fin-shaped structure 210, in accordance with some embodiments. FIGS. 18A and 18B are cross-sectional views of the GAA device 400 after forming the dummy gate structure 220. The dummy gate structure 220 is formed across the fin-shaped structure 210, along the sidewalls and over the top surface of the fin-shaped structure 210.

The dummy gate structure 220 includes a dummy gate stack (222, 224) and gate spacers 226. Accordance to embodiments of the present disclosure, the dummy gate stack (222, 224) will be replaced with a metal gate stack.

In some embodiments, the dummy gate stack (222, 224) includes a dummy gate dielectric 222 and a dummy gate electrode 224 on the dummy gate dielectric 222. In some embodiments, the dummy gate stack (222, 224) may further include a dummy gate cap (not shown) on top of the dummy gate electrode 224.

In some embodiments, the dummy gate dielectric 222 may be made of silicon oxide, silicon nitride, or silicon oxynitride. The dummy gate electrode 224 may be made of silicon such as polycrystalline silicon or amorphous silicon. In some embodiments, the dummy gate stack (222, 224) may be formed by first conformally depositing a dummy gate dielectric layer over the fin-shaped structure 210 and the isolation feature 216. A dummy gate electrode layer is then blanketly deposited on the dummy gate dielectric layer such that the fin-shaped structure 210 is fully embedded in the dummy gate electrode layer. The thickness of the dummy gate dielectric layer may range from about 1 nm to about 5 nm in some embodiments. The thickness of the dummy gate electrode layer may range from about 100 nm to about 200 nm in some embodiments. In some embodiments, the dummy gate electrode layer is subjected to a planarization operation. The dummy gate dielectric layer and the dummy gate electrode layer may be deposited using CVD, PECVD, PVD, ALD, or other suitable deposition processes. Subsequently, the dummy gate dielectric layer and the dummy gate electrode layer are patterned using photolithography and etching processes. For example, a photoresist layer (not shown) is applied over the sacrificial electrode layer and lithographically patterned by lithographic exposure and development. The pattern in the photoresist layer is sequentially transferred into the sacrificial electrode layer and the sacrificial dielectric layer by at least one anisotropic etching process, thereby forming the dummy gate stack (222, 224). The anisotropic etching process may be a dry etching process, for example, RIE, a wet etching process, or a combination thereof. If not completely consumed, the remaining photoresist layer after formation of the dummy gate stack (222, 224) is removed by, for example, ashing.

The gate spacers 226 are disposed along sidewalls of the dummy gate stack (222, 224). In some embodiments, the gate spacers 226 may include a dielectric material such as, for example, an oxide, a nitride, an oxynitride, or combinations thereof. In some embodiments, the gate spacers 226 are made of silicon nitride. In some embodiments, the gate spacers 226 may be formed by first depositing a conformal gate spacer material layer on exposed surfaces of the dummy gate stack (222, 224), the fin-shaped structure 210, and the isolation features 216 and then etching the gate spacer material layer to remove horizontal portions of the gate spacer material layer. In some embodiments, the gate spacer material layer may be deposited, for example, by CVD, PECVD, or ALD. In some embodiments, the gate spacer material layer may be etched by dry etch such as, for example, plasma etching or RIE. Vertical portions of the gate spacer material layer present on the sidewalls of dummy gate stack (222, 224) constitute the gate spacers 226.

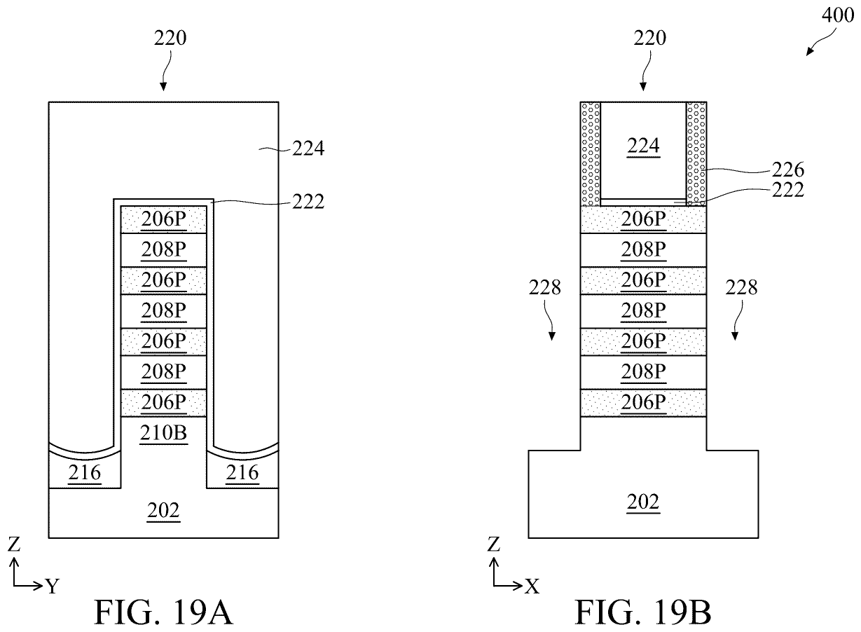

Referring to FIGS. 16 and 19A-19B, the method 300 proceeds to operation 310, where source/drain trenches 228 are formed in the fin-shaped structure 210, in accordance with some embodiments. FIGS. 19A and 19B are cross-sectional views of the GAA device 400 after forming the source/drain trenches 228.

In some embodiments, the sacrificial semiconductor portions 206P and the channel semiconductor portions 208P of the fin-shaped structure 210 in the source/drain regions are etched using the dummy gate structure 220 as an etch mask to form source/drain trenches 228. The etch may be performed by a dry etching process such as plasma etching or RIE. An example dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. Alternatively, the etching may be performed by a wet etching process that uses an etchant such as APM, TMAH, or NH₄OH. As shown in FIG. 19B, sidewalls of the sacrificial semiconductor portions 206P and the channel semiconductor portions 208P are exposed in the source/drain trenches 228. In some embodiments, the substrate 202 may also be partially etched. Accordingly, the bottom surfaces of the source/drain trenches 228 may be leveled with the top surface of the base portion 210B or lower than the top surface of the base portion 210B.

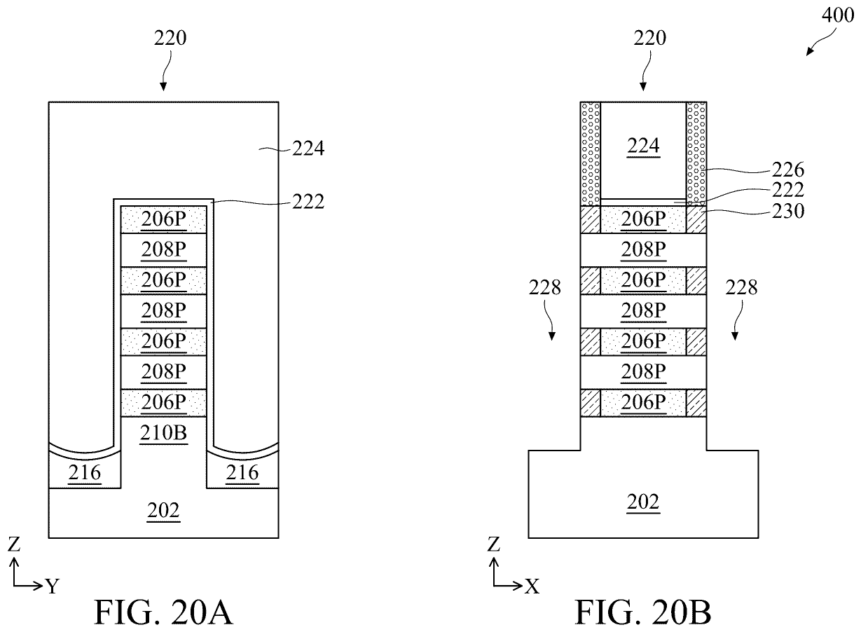

Referring to FIGS. 16 and 20A-20B, the method 300 proceeds to operation 312, wherein inner spacers 230 are formed, in accordance with some embodiments. FIGS. 20A and 20B are cross-sectional views of the GAA device 400 after forming the inner spacers 230. The inner spacers 230 have generally the same lateral dimensions as the gate spacers 226 and contact sidewalls of the sacrificial semiconductor portions 206P. This operation has been described above with reference to FIGS. 1 and 6A-6B.

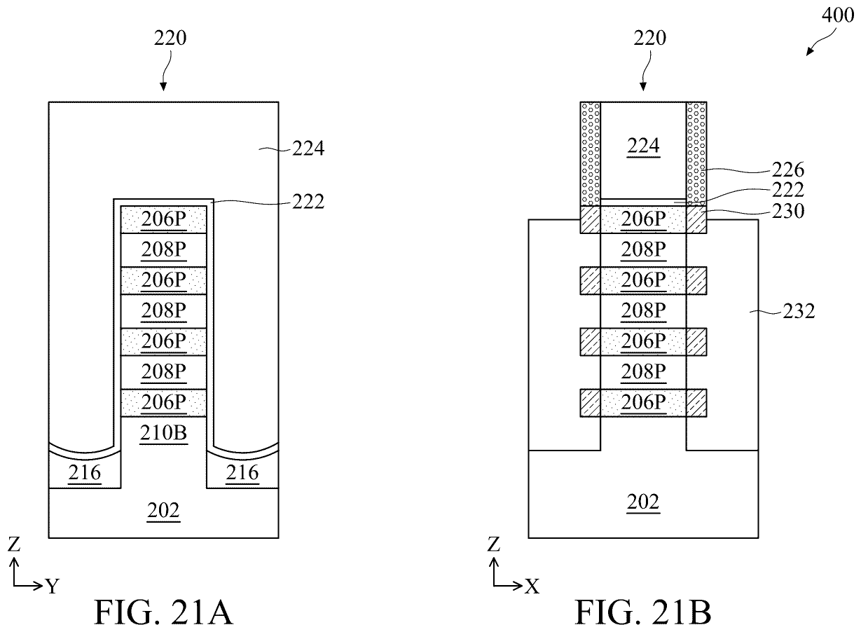

Referring to FIGS. 16 and 21A-21B, the method 300 proceeds to operation 314, where source/drain features 232 are formed in the source/drain trenches 228, in accordance with some embodiments. FIGS. 21A and 21B are cross-sectional views of the GAA device 400 after forming the source/drain features 232. The source/drain features 232 are disposed on opposite sides of the dummy gate structure 220, the sacrificial semiconductor portions 206P, and the channel semiconductor portions 208P such that the source/drain features 232 are in contact with the channel semiconductor portions 208P but are separated from the sacrificial semiconductor portions 206P by the inner spacers 230. This operation has been described above with reference to FIGS. 1 and 7A-7B.

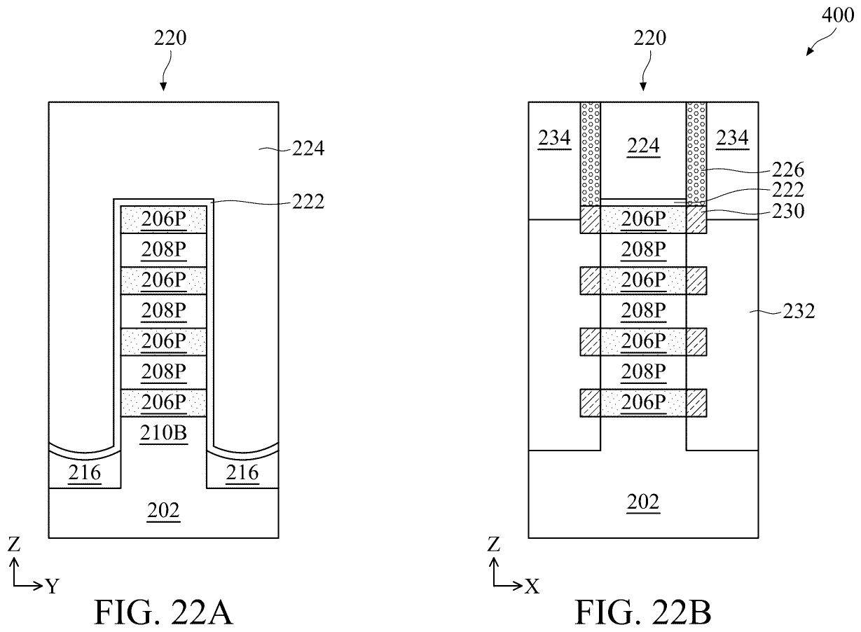

Referring to FIGS. 16 and 22A-22B, the method 300 proceeds to operation 316, where an interlayer dielectric (ILD) layer 234 is formed over the source/drain features 232 and the isolation feature 216, in accordance with some embodiments. FIGS. 22A and 22B are cross-sectional views of the GAA device 400 after forming the ILD layer 234. This operation has been described above with reference to FIGS. 1 and 8A-8B.

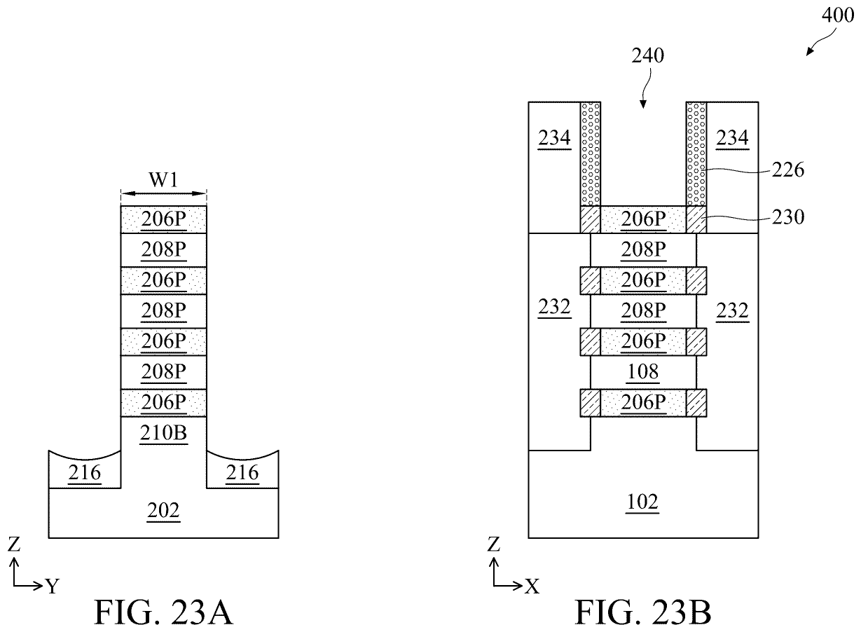

Referring to FIGS. 16 and 23A-23B, the method 300 proceed to operation 318, where the dummy gate stack (222, 224) including the dummy gate dielectric 222 and the dummy gate electrode 224 are removed, in accordance with some embodiments. FIGS. 23A and 23B are cross-sectional views of the GAA device 400 after removing the dummy gate stack (222, 224). The removal of the dummy gate stack (222, 224) forms a gate trench 240 that exposes the sacrificial semiconductor portions 206P and the channel semiconductor portions 208P in the channel region of the fin-shaped structure 210. This operation has been described above with reference to FIGS. 1 and 9A-9B.

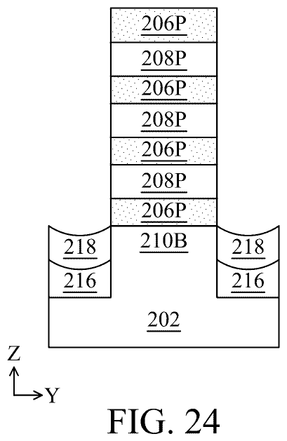

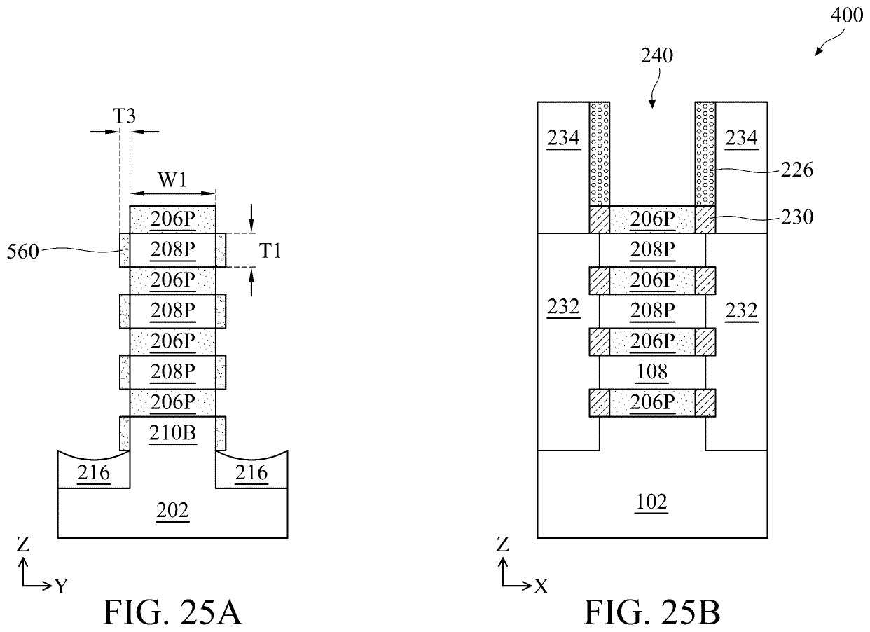

In some embodiments, after removing the dummy gate stack (222, 224), a base mask layer 218 may be formed on the isolation feature 216 to surround the exposed portion of the base portion 210B above the isolation feature 216 (FIG. 24). The base mask layer 218 prevents the subsequent epitaxial growth of semiconductor material from the base portion 210B. As a result, a semiconductor cap (e.g., 560 of FIG. 25A) will not be formed on the base portion 210B, thereby preventing the increase in I_{off} caused by the bottom planar transistor. The formation of the base mask layer 218 is optional.

Referring to FIGS. 16 and 25A-25B, the method 300 proceeds to operation 320, where semiconductor caps 560 are formed on opposite sidewalls of the channel semiconductor portions 208P and the base portion 210B, in accordance with some embodiments. FIGS. 25A and 25B are cross-sectional views of the GAA device 400 after forming the semiconductor caps 560 on the opposite sidewalls of the channel semiconductor portions 208P and the base portion 210B.

The semiconductor caps 560 are designed to be consumed during the subsequent channel nanosheet formation process, thereby serving as sacrificial components to prevent the width loss of the channel semiconductor portions 208P. The semiconductor caps 560 are composed of the same semiconductor material as the channel semiconductor portions 208P. For instance, in some embodiments, where the channel semiconductor portions 208P are made of Si, the semiconductor caps 560 are also composed Si. Interfaces may exist between the channel members 208A and their respective semiconductor caps 560, or there may be no interfaces therebetween.

The semiconductor caps 560 may be formed by selectively depositing a semiconductor material on the sidewalls of the channel semiconductor portions 208P and the base portion 210B exposed by the gate trench 240 using ALD, CVD, PVD, or other suitable methods. The thickness T3 of the semiconductor caps 560 may range from about 0.5 nm to about 4 nm. In some embodiments, the thickness T3 of the semiconductor caps 560 is about 0.75 nm, about 1 nm, about 1.5 nm, about 2 nm, about 2.5 nm, about 3 nm, or about 3.5 nm. The topmost sacrificial semiconductor portion 206P within the fin-shaped structure 210 helps to prevent the growth of a semiconductor cap on the topmost surface of the fin-shaped structure 210.

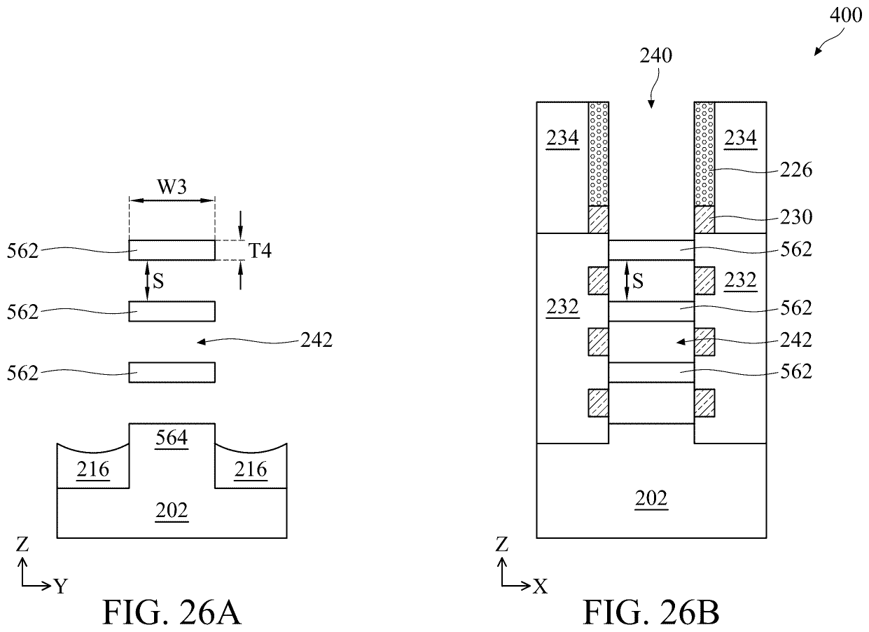

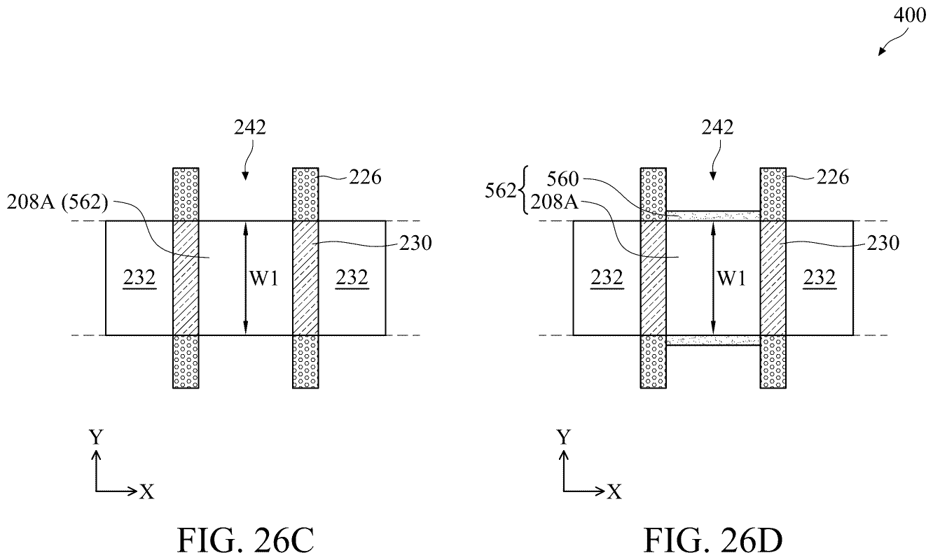

Referring to FIGS. 16 and 26A-26B, the method 300 proceeds to operation 322, where the sacrificial semiconductor portions 206P are removed, in accordance with some embodiments. FIGS. 26A and 26B are cross-sectional views of the GAA device 400 after removing the sacrificial semiconductor portions 206P.

The selective removal of the sacrificial semiconductor portions 206P releases the channel semiconductor portions 208P to form channel members 208A. In some embodiments, the sacrificial semiconductor portions 206P may be removed by a selective etching process using an etchant that is selective to the material of sacrificial semiconductor portions 206P, such that the sacrificial semiconductor portions 206P are removed without substantially attacking the channel semiconductor portions 208P and the semiconductor caps 560. In some embodiments, the etching process is an isotropic etching process which can be a dry etching process or a wet etching process. In some embodiments, the selective etching process may include oxidizing the sacrificial semiconductor portions 206P using a suitable oxidizer, such as ozone. Thereafter, the oxidized sacrificial semiconductor portions 206P may be selectively removed. In some embodiments, when the channel semiconductor portions 208P and the semiconductor caps 560 include Si, while the sacrificial semiconductor portions 206P include SiGe, the sacrificial semiconductor portions 206P may be selectively removed by applying an HCl gas at a temperature of about 500° C. to about 700° C., or applying a gas mixture of CF₄, SF₆, and CHF₃. The inner spacers 230 serve as etch stop layers to protect the source/drain features 232 during the etching process. The etching process also removes the semiconductor caps 560. In some embodiments, the semiconductor caps 560 are completely consumed. The resulting channel members 208A, now also referred to as channel nanostructures 562, maintain the original width W1 of the channel semiconductor portions 208P. In some embodiments, the channel nanostructures 562 are nanosheets.

FIGS. 26C and 26D are plan views of the channel and source/drain regions illustrating channel nanostructures 562 formed after the etching process. In some embodiments, the semiconductor caps 560 formed on the sidewalls of the base portion 210B are completely consumed by the etching process. The resulting channel nanostructure 562 is formed solely from the channel member 208A, with sidewalls aligned with the sidewalls of the inner spacers 230 along the Y-direction, as shown in FIG. 26C. The channel nanostructure 562 thus has the same width W1 as that of the channel semiconductor portions 208P. In other embodiments, the semiconductor caps 560 formed on the sidewalls of the base portion 210B are partially consumed by the etching process. As shown in FIG. 26D, the resulting channel nanostructure 562 includes the channel member 208A and the remaining portions of semiconductor caps 560. The sidewalls of the channel nanostructure 562 extend beyond the sidewalls of the inner spacers 230 along the Y-direction.

In some embodiments, the semiconductor cap 560 formed on the sidewalls of the base portion 210B is also completely consumed by the etching process. The remaining portion of the base portion 210B is referred to herein as the mesa structure 564. In instances where the semiconductor cap 560 on the sidewalls of the base portion 210B has a thickness greater than the thickness of those semiconductor caps 560 on the sidewalls of the channel members 208A, the semiconductor caps 560 formed on the sidewalls of the base portion 210B may be partially consumed during the etching process. The mesa structure 564 may retain the remaining portions of the semiconductor caps 560.

In some embodiments, after removing the sacrificial semiconductor portions 206P, a trimming operation may be performed to reduce the thickness of the channel nanostructure 562, thereby improving the gate fill window. The trimming operation can utilize any suitable etching process, such as dry etching, wet etching, or a combination of both. Following the trimming operation, the channel nanostructure 562 may have a width W3 ranging from about 10 nm to about 90 nm, for example, from about 12.5 nm to about 45 nm, and a thickness T4 ranging from about 4 nm to about 7 nm.

As a result of the removal of the sacrificial semiconductor portions 206P and nanosheet trimming, gaps 242 (e.g., empties spaces) are formed between adjacent channel nanostructures 562, and between the bottommost channel nanostructure 562 and the base portion 210B. The gaps 242 define the spacing S between adjacent channel nanostructures 562. In some embodiments, the spacing between the adjacent channel nanostructures 562 (also referred to as sheet-to-sheet spacing) may range from about 8 nm to about 15 nm.

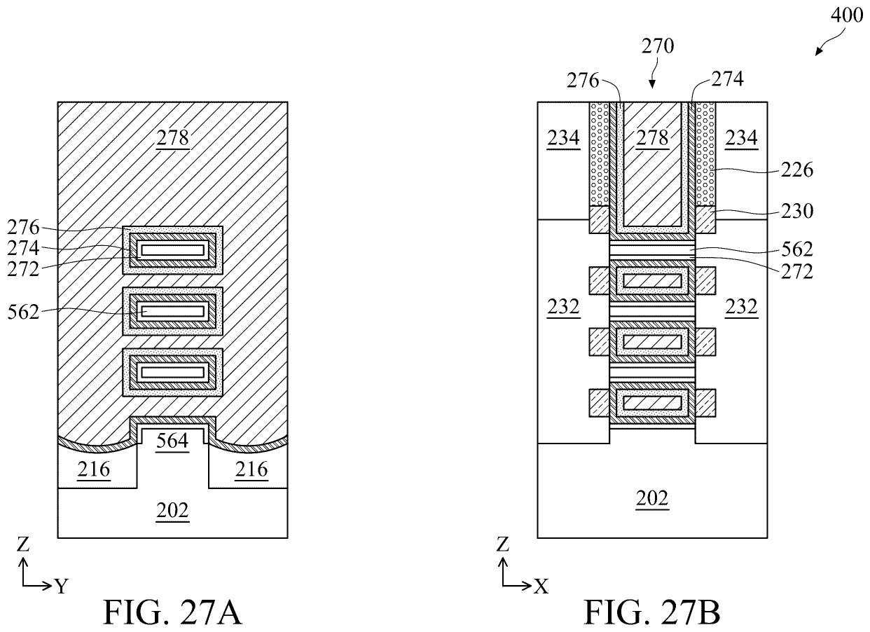

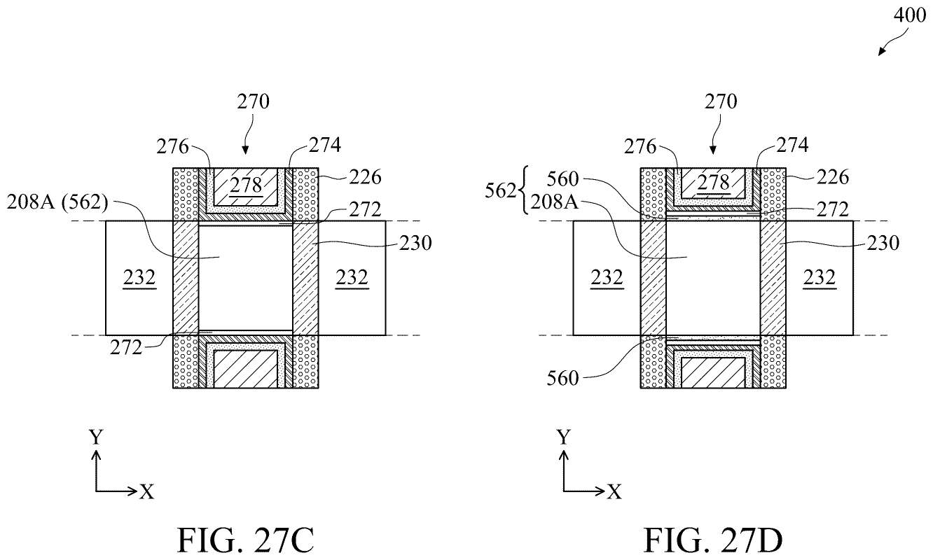

Referring to FIGS. 16 and 27A-27B, the method 300 proceeds to operation 324, where a gate stack 270 is formed in the gate trench 240 and the gaps 242, in accordance with some embodiments. FIGS. 27A and 27B are cross-sectional views of the GAA device 400 after forming the gate stack 270. The gate stack 270 is deposed over and between the channel nanostructures 562, respectively and over the mesa structure 564. In some embodiments, the gate stack 270 includes an interfacial layer 272, a gate dielectric layer 274, a work function layer 276, and a gate electrode layer 278.

The interfacial layer 272 is formed on the exposed surfaces of the channel nanostructures 562 and the top surface of the mesa structure 564. The interfacial layer 272 promotes adhesion of the gate dielectric layer 274 to the channel nanostructures 562. In some embodiments, the interfacial layer 272 may include a dielectric material such as silicon oxide. In some embodiments, the interfacial layer 272 may be formed by chemical oxidation or thermal oxidation of surface portions of the channel nanostructures 562 and the mesa structure 564. For example, in some embodiments, the interfacial layer 272 is formed using an ozonated deionized water comprising ozone. The thickness of the interfacial layer 272 ranges from about 0.5 nm to about 1.5 nm. In some embodiments, the interfacial layer 272 is about 1 nm thick, achieved by oxidizing around 1 nm of the channel nanostructures 562. The sidewalls of the interfacial layer 272 align with the sidewalls of the inner spacers 230.

The gate dielectric layer 274 is conformally deposited over the interfacial layer 272. The gate dielectric layer 274 wraps around the channel nanostructures 562, and is on the sidewalls of the gate trench 240. In some embodiments, the gate dielectric layer 274 may include a high-k dielectric material having a dielectric constant greater than silicon dioxide. Examples of high-k dielectric materials include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), titanium oxide (TiO₂), and hafnium oxide-alumina (HfO₂—Al₂O₃) alloy. The gate dielectric layer 274 may be formed by CVD, ALD or other suitable conformal deposition methods. In some embodiments, the gate dielectric layer 274 is formed using a conformal deposition process such as ALD in order to ensure that the high-k gate dielectric layer 274 has a uniform thickness around each of channel nanostructures 562. The gate dielectric layer 274 may be formed to have a thickness ranging from about 1 nm to about 2.5 nm. In some embodiments, the gate dielectric layer 274 may be formed to have a thickness of about 1.5 nm.

FIGS. 27C and 27D are plan views of the channel and source/drain regions illustrating the interfacial layer 272 formed. In instances where the channel nanostructures 562 have the sidewalls aligned with the sidewalls of the inner spacers 230, the interfacial layer 272 extends between the inner spacers 230 in the X-direction and has sidewalls aligned with the sidewalls of the inner spacers 230 in the Y-direction, as shown in FIG. 27C. If the channel nanostructures 562 protrude beyond the sidewalls of inner spacers 230 in the Y-direction, the interfacial layer 272 extends between the gate spacers 226 in the X-direction, with sidewalls contacting the gate spacers 226, as depicted in FIG. 27D.

Subsequently, a work function layer 276 is deposited over the gate dielectric layer 274. For an n-type FET, the work function layer 276 may include an n-type work function layer adapted to tune the threshold voltage for n-type FET. Suitable n-type work function materials include, but are not limited to, aluminum (Al), titanium aluminum (TiAl), titanium aluminum carbide (TiAlC), tantalum aluminum carbide (TaAlC), tantalum aluminum silicide (TaSiAl), tantalum silicon carbide (TaSiC), tantalum silicide (TaSi), hafnium carbide (HfC), and combinations thereof. For a p-type FET, the work function layer 276 may include a p-type work function layer adapted to tune the threshold voltage for p-type FET. In some embodiments, the p-type work function layer includes tungsten (W), molybdenum (Mo), tungsten nitride (WN), tungsten carbon nitride (WCN), tantalum silicon nitride (TaSiN), or tantalum nitride (TaN). The work function layer may be formed by a conformal deposition process such as, for example, ALD or CVD. In some embodiments, the work function layer 276 may be formed to have a thickness ranging from about 1.5 nm to about 2.5 nm.

Afterwards, the gate electrode layer 278 is formed on the work function layer 276 to fill any remaining volumes in the gate trench 240 and the gaps 242. The gate electrode layer 278 may include a conductive material such as tungsten, cobalt, ruthenium, iridium, molybdenum, copper, aluminum, or combinations thereof. The gate electrode layer 278 may be formed by any suitable deposition process such as CVD, PECVD, PVD, or electrochemical plating.

Next, excess portions of the gate dielectric layer 274, the work function layer 276, and the gate electrode layer 278 deposited on the top surface of the ILD layer 234 and the gate spacers 226 are removed in a planarization process such as a CMP process to form the gate stack 270. The top surface of the gate stack 270 may be coplanar with the top surfaces of the ILD layer 234 and the gate spacers 226. The gate stack 270 surrounds the channel nanostructures 562. Between the channel nanostructures 562, the gate electrode layer 278 is circumferentially surrounded (in the cross-sectional view) by the work function layer 276, which is then circumferentially surrounded by the gate dielectric layer 274. In the portion of the gate stack 270 formed over the topmost channel nanostructure 562, the gate electrode layer 278 is formed over the work function layer 276. The work function layer 276 wraps around the gate electrode layer 278. The gate dielectric layer 274 also wraps around the work function layer 276.

Additional processing may be performed to finish the fabrication of the GAA device 400. For example, gate contact (not illustrated for simplicity) and the source/drain contacts may be formed to electrically couple to the gate stack 270 and the source/drain features 232, respectively. An interconnect structure may then be formed over the source/drain contacts and the gate contact. The interconnect structure may include a plurality of dielectric layers surrounding metallic features, including conductive traces and conductive vias, which form electrical connection between devices on the substrate 202, such as the GAA device 400.

The embodiments of the present disclosure provide advantages. By using semiconductor caps as sacrificial components to prevent the sheet width loss of the channel semiconductor portions, the dumbbell-shaped channel profile can be improved from over 2 nm to 1 nm or less, or completely eliminated. This increase in channel width helps to reduce overlapping area between the source/drain features and the metal gate, thereby reducing parasitic capacitance. Additionally, the channel width increase enhances current flow. As a result, the device performance can be increased.

One aspect of this description relates to a method for forming a semiconductor device. The method includes forming a fin-shaped structure over a substrate. The fin-shaped structure includes a fin stack portion of alternatively stacked first semiconductor portions and second semiconductor portions. Next, a dummy gate structure comprising a dummy gate stack and gate spacers on sidewalls of the dummy gate stack is formed. The dummy gate stack is across a channel region of the fin-shaped structure. Next, source/drain features are formed over source/drain regions of the fin-shaped structure on opposite sides of the dummy gate structure. Next, the dummy gate stack is removed to form a gate trench exposing sidewalls of the first semiconductor portions and the second semiconductor portions. Next, the first semiconductor portions are selectively removed to release the second semiconductor portions in the channel region as channel members. Next, a dielectric material is deposited to fill gaps between the channel members. Next, semiconductor caps are deposited on the sidewalls of the channel members. Next, the deposited dielectric material in the gaps is removed, followed by forming a gate stack to surround the semiconductor caps and the channel members. The gate stack fills the gaps.

Another aspect of this description relates to a method for forming a semiconductor device. The method includes forming a fin-shaped structure over a substrate. The fin-shaped structure includes a fin stack portion of alternatively stacked first semiconductor portions and second semiconductor portions. Next, a dummy gate structure comprising a dummy gate stack is formed across a channel region of the fin-shaped structure and gate spacers on sidewalls of the dummy gate stack. Next, source/drain features are formed over source/drain regions of the fin-shaped structure on opposite sides of the dummy gate structure. Next, the dummy gate stack is removed to form a gate trench exposing sidewalls of the first semiconductor portions and the second semiconductor portions. Next, semiconductor caps are selectively grown on the sidewalls of the second semiconductor portions. Next, the first semiconductor portions are selectively removed to release the second semiconductor portions in the channel region as channel members, followed by forming a gate stack to surround the channel members, wherein the gate stack fills gaps between the channel members.

Still another aspect of this description relates to a semiconductor device. The semiconductor device includes a plurality of suspended channel nanostructures over a substrate and having a length dimension in a first direction and a width dimension in a second direction traversing the first direction, each of the plurality of channel nanostructures comprising a channel member and semiconductor caps on opposite sidewalls of the channel member along the second direction. The semiconductor further includes a gate structure comprising a gate stack surrounding a channel region of each of the plurality of channel nanostructures and filing gaps between the channel nanostructures. Sidewalls of the gate stack along the first direction are surrounded by inner spacers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a fin-shaped structure over a substrate, the fin-shaped structure comprising a fin stack portion of alternatively stacked first semiconductor portions and second semiconductor portions;
forming a dummy gate structure comprising a dummy gate stack and gate spacers on sidewalls of the dummy gate stack, the dummy gate stack across a channel region of the fin-shaped structure;
forming source/drain features over source/drain regions of the fin-shaped structure on opposite sides of the dummy gate structure;
removing the dummy gate stack to form a gate trench exposing sidewalls of the first semiconductor portions and the second semiconductor portions;
selectively removing the first semiconductor portions to release the second semiconductor portions in the channel region as channel members;
depositing a dielectric material to fill gaps between the channel members;
selectively growing semiconductor caps on the sidewalls of the channel members;
removing the deposited dielectric material in the gaps; and
forming a gate stack to surround the semiconductor caps and the channel members, wherein the gate stack fills the gaps.

2. The method of claim 1, further comprising forming a hard mask portion over the fin stack portion, wherein the hard mask portion is in contact with a topmost channel member of the channel members after removing the first semiconductor portions, and the gate stack surrounds a portion of the hard mask portion and fills a gap between a topmost channel member and the hard mask portion.

3. The method of claim 1, further comprising:
after forming the dummy gate structure, recessing source/drain regions of the fin-shaped structure to expose sidewalls of the first semiconductor portions and the second semiconductor portions in the channel region;
selectively recessing the exposed sidewalls of the first semiconductor portions to form inner spacer recesses; and
forming inner spacers in the inner spacer recesses, wherein the source/drain features contact the inner spacers.

4. The method of claim 3, wherein the sidewalls of the semiconductor caps exposed by the gate trench are recessed relative to sidewalls of the inner spacers.

5. The method of claim 3, wherein the sidewalls of the semiconductor caps exposed by the gate trench are protruded beyond sidewalls of the inner spacers.

6. The method of claim 3, wherein the sidewalls of the semiconductor caps exposed by the gate trench align with sidewalls of the inner spacers.

7. The method of claim 1, wherein the semiconductor caps have a flat surface or a curved surface.

8. The method of claim 1, wherein the dielectric material comprises aluminum oxide.

9. The method of claim 1, wherein the fin-shaped structure further comprises a base portion beneath the fin stack portion, wherein selectively growing semiconductor caps on the sidewalls of the channel members also forms another semiconductor cap on sidewalls of the base portion.

10. The method of claim 1, wherein the another semiconductor cap on the sidewalls of the base portion has a thickness the same as or greater than a thickness of the semiconductor caps on the sidewalls of the channel members.

11. A method for forming a semiconductor device, comprising:
forming a fin-shaped structure over a substrate, the fin-shaped structure comprising a fin stack portion of alternatively stacked first semiconductor portions and second semiconductor portions;
forming a dummy gate structure comprising a dummy gate stack across a channel region of the fin-shaped structure and gate spacers on sidewalls of the dummy gate stack;
forming source/drain features over source/drain regions of the fin-shaped structure on opposite sides of the dummy gate structure;
removing the dummy gate stack to form a gate trench exposing sidewalls of the first semiconductor portions and the second semiconductor portions;
selectively growing semiconductor caps on the sidewalls of the second semiconductor portions;
selectively removing the first semiconductor portions to release the second semiconductor portions in the channel region as channel members; and
forming a gate stack to surround the channel members, wherein the gate stack fills gaps between the channel members.

12. The method of claim 11, further comprising:
after forming the dummy gate structure, recessing source/drain regions of the fin-shaped structure to expose sidewalls of the first semiconductor portions and the second semiconductor portions in the channel region;
selectively recessing the exposed sidewalls of the first semiconductor portions to form inner spacer recesses; and
forming inner spacers in the inner spacer recesses, wherein the source/drain features contact the inner spacers.

13. The method of claim 11, wherein the selective removing the first semiconductor portions is performed by an isotropic etching process.

14. The method of claim 13, wherein the semiconductor caps are completely removed by the isotropic etching process.

15. The method of claim 13, wherein the semiconductor caps are partially removed by the isotropic etching process, wherein the gate stack surrounds the remaining portions of the semiconductor caps and the channel members.

16. A semiconductor device, comprising
a plurality of suspended channel nanostructures over a substrate and having a length dimension in a first direction and a width dimension in a second direction traverse the first direction, each of the plurality of channel nanostructures comprising a channel member and semiconductor caps on opposite sidewalls of the channel member along the second direction; and
a gate stack surrounding a channel region of each of the plurality of channel nanostructures and filling gaps between the channel nanostructures, wherein sidewalls of the gate stack along the first direction are surrounded by inner spacers.

17. The semiconductor device of claim 16, wherein sidewalls of the semiconductor caps are aligned with sidewalls of the inner spacers along the second direction.

18. The semiconductor device of claim 16, wherein sidewalls of the semiconductor caps are recessed with respect to sidewalls of the inner spacers along the second direction.

19. The semiconductor device of claim 16, wherein sidewalls of the semiconductor caps protrude beyond sidewalls of the inner spacers along the second direction.

20. The semiconductor device of claim 16, further comprising a hard mask portion over a topmost channel nanostructure of the plurality of the channel nanostructures, the gate stack surrounding the topmost channel nanostructure and filling a gap between the hard mask portion and the topmost channel nanostructure.
